(19) United States
(12) Patent Application Publication
(10) Pub. No.: US 2005/0253137 A1
(43) Pub. Date: Nov. 17, 2005

(54) Nanoscale arrays, robust nanostructures, and related devices

(75) Inventors: Dongmok Whang, Cambridge, MA (US); Song Jin, Madison, WI (US); Yue Wu, Cambridge, MA (US); Michael McAlpine, Cambridge, MA (US); Robin S. Friedman, Cambridge, MA (US); Charles M. Lieber, Lexington, MA (US)

Correspondence Address: WOLF GREENFIELD & SACKS, PC;FEDERAL RESERVE PLAZA, 600 ATLANTIC AVENUE, BOSTON, MA, 02210-2211, US

(73) Assignee: President and Fellows of Harvard College, Cambridge, MA (US)

(21) Appl. No.: 10/995,075

(22) Filed: Nov. 22, 2004

Related U.S. Application Data
(60) Provisional application No. 60/524,301, filed on Nov. 20, 2003.
(60) Provisional application No. 60/551,634, filed on Mar. 8, 2004.

(51) Int. Cl. H01L 29/06

(52) U.S. Cl. 257/40

(57) ABSTRACT

The present invention relates generally to nanotechnology and sub-microelectronic circuitry, and more particularly to nanoelectronics. One aspect of the invention is directed to nanostructures on substrates. In some cases, the substrate may be or comprise glass and/or polymers, and in some cases, the substrate may be flexible and/or transparent. The present invention is also directed, according to another aspect, to techniques for fabricating nanostructures on substrates. For example, monolayers of nanoscale semiconductors may be etched, e.g. photolithographically, to yield discrete and/or predetermined arrays of nanoscale semiconductors and other articles on a substrate. In one embodiment, the array may include hundreds, thousands, or more of electronic components such as field-effect transistors. Such arrays may be connected to electrodes using photolithographic techniques, and in some cases, without the need for registering individual semiconductor-metal contacts.

### RELATED APPLICATIONS

This application claims the benefit of U.S. Provisional Patent Application Ser. No. 60/524,301, filed Nov. 20, 2003, entitled “Nanoscale Arrays and Related Devices,” by Whang, et al. This application also claims the benefit of U.S. Provisional Patent Application Ser. No. 60/551,634, filed Mar. 8, 2004, entitled “Robust Nanostructures,” by McAlpine, et al. Each of the above applications is incorporated herein by reference.

### FIELD OF INVENTION

The present invention relates generally to nanotechnology and sub-microelectronic devices that can be used in circuitry, and more particularly to nanoelectronics, i.e., nanoscale semiconductors and other articles, arrays of such nanoscale semiconductors and other articles, and associated methods and devices. Articles and devices of size greater than the nanoscale are also included.

### BACKGROUND

Interest in nanotechnology, in particular sub-microelectronic technologies such as semiconductor quantum dots and nanowires, has been motivated by the challenges of chemistry and physics at the nanoscale, and by the prospect of utilizing these structures in electronic, optical, and related devices. While nanoscopic articles might be well-suited for transport of charge carriers and excitons (e.g. electrons, electron pairs, etc.) and thus may be useful as building blocks in nanoscale electronics, optics, and other applications, much of nanotechnology and nanoelectronics is not well-developed. Thus there is a need in the art for new and improved articles and techniques involving nanoscale devices.

### SUMMARY OF THE INVENTION

The present invention relates to nanoscale semiconductors and other articles, arrays of such nanoscale semiconductors and other articles, and associated methods and devices, as well as to methods of making and using them. Most aspects and embodiments of the invention involve nanometer-scale articles and devices, but larger articles and devices are provided as well. The subject matter of the present invention involves, in some cases, interrelated products, alternative solutions to a particular problem, and/or a plurality of different uses of one or more systems and/or articles.

One significant aspect of the invention involves formation of desired patterns of nanoscale articles on surfaces. Another significant aspect involves nanoscale articles in association with a variety of substrates including polymeric, flexible, and/or glass substrates. Some of the other aspects and embodiments of the invention follow.

One aspect of the present invention is directed to an article. In one set of embodiments, the article includes a substrate comprising a polymer, and an electrically conductive nanoscale wire proximate the substrate, the nanoscale wire comprising at least one portion having a smallest width of less than about 100 nm.

The invention, in another aspect, is a method. The method, according to one set of embodiments, includes an act of positioning a nanoscale wire, having at least one portion having a smallest width of less than about 100 nm, proximate a substrate comprising a polymer. In another set of embodiments, the method includes an act of removing, from a surface of a substrate having a plurality of substantially aligned nanoscale wires disposed thereon, a portion of the plurality of nanoscale wires, while retaining substantial alignment of the nanoscale wires remaining on the surface.

The method, according to yet another set of embodiments, includes acts of providing a plurality of nanoscale wires disposed on a surface at a density of at least 1 wire/micron², and removing nanoscale wires from the surface in a first pattern while leaving nanoscale wires in a second pattern complementary to the first pattern, the second pattern comprising a plurality of ordered regions of nanoscale wires. In some cases, each region includes nanoscale wires positioned relative to each other in a manner similar from region to region. In one embodiment, at least two of the regions separated from each other by a portion of the surface, essentially free of nanoscale wires, at a minimum distance of at least 5 nm.

In another aspect, the present invention is directed to a method of making one or more of the embodiments described herein. In yet another aspect, the present invention is directed to a method of using one or more of the embodiments described herein. In still another aspect, the present invention is directed to a method of promoting one or more of the embodiments described herein.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1E are schematic diagrams of a method and system of forming nanostructures on a substrate, according to one embodiment of the invention;

FIGS. 2A-2C are schematic diagrams of a process and system for making a nanoimprint on a polymer substrate, in another embodiment of the invention;

FIGS. 3A-3E are photocopies of optical and SEM images of arrays of nanoscale wires, in accordance with another embodiment of the invention;

FIGS. 4A-4C are images and data from an embodiment of the invention comprising a nanoscale wire crossing an imprint-patterned metal gate electrode;

FIG. 5 is a schematic diagram of a method of forming nanostructures on a substrate, according to another embodiment of the invention;

FIGS. 6A-6B are graphs illustrating data characterizing certain nanowire devices on glass substrates, in certain embodiments of the invention;

FIGS. 7A-7C are graphs illustrating data characterizing certain nanowire devices on a polymer substrates, in certain embodiments of the invention;

FIG. 8 is a graph illustrating data characterizing a flexible nanowire device, in another embodiment of the invention;

FIGS. 9A-9E are images of and data from an embodiment of the invention including light-emitting nanoscale wires;

FIGS. 10A-10C illustrate a fabrication method for large-scale arrays according to one embodiment of the invention;

FIGS. 11A-11F illustrate various arrays including single nanoscale wire transistors;

FIGS. 12A-12E are a schematic diagram of the alignment of nanowires on the surface of a Langmuir-Blodgett trough;

FIGS. 13A-13D are SEM images of substantially aligned nanowires;

FIGS. 14A-14D are SEM images of substantially aligned nanowires that have been transferred;

FIGS. 15A-15E illustrate hierarchical patterning of nanowire lithographically defined structures;

FIGS. 16A-16D are a schematic diagram of the compression of nanowires in a Langmuir-Blodgett trough;

FIGS. 17A-17E are images of substantially aligned nanowires on a substrate;

FIGS. 18A-18C illustrate hierarchical patterning of nanowire arrays; and

FIGS. 19A-19D illustrate hierarchical patterning of arrays of crossed nanowires.

### DETAILED DESCRIPTION

The present invention relates generally to nanotechnology and sub-microelectronic circuitry, and more particularly to nanoelectronics. One aspect of the invention is directed to nanostructures on substrates. In some cases, the substrate may be or comprise glass and/or polymers, and in some cases, the substrate may be flexible and/or transparent. The present invention is also directed, according to another aspect, to techniques for fabricating nanostructures on substrates. For example, nanoscale structures such as nanowires can be positioned on a substrate in a first arrangement or pattern, optionally manipulated to form a second arrangement, and ablated (e.g. lithographically) such that at least portions of some of the nanostructures are removed from the surface, thereby defining a subsequent arrangement of the nanostructures on the surface. In some cases, entire nanostructures are removed via ablation, and the subsequent pattern includes fewer nanostructures than the first or second pattern. In other cases, only portions of some or all of the nanostructures are removed via ablation, and the subsequent pattern includes all of the nanostructures present in the first or second pattern, but portions of some or all of those nanostructures have been removed. More specifically, monolayers of nanoscale semiconductors may be etched, e.g. photolithographically, to yield discrete and/or predetermined arrays of nanoscale semiconductors and other articles on a substrate. In one embodiment, the array may include hundreds, thousands, or more of electronic components such as field-effect transistors. Such arrays may be connected to electrodes using photolithographic techniques, and in some cases, without the need for registering individual semiconductor-metal contacts.

The present invention, in one aspect, includes a nanoscopic wire or other nanostructured material comprising one or more semiconductor and/or metal compounds. In some cases, the semiconductors and/or metals may be chemically and/or physically combined, for example, as in a doped nanoscopic wire. The nanoscopic wire may be, for example, a nanorod, a nanowire, a nanowhisker, or a nanotube. The nanoscopic wire may be used in a device, for example, as a semiconductor component, a pathway, etc. In some cases, the nanoscopic wire may further include dopants.

One aspect of the invention provides for the assembly, or controlled placement, of nanoscale wires on a surface. In some cases, multiple techniques, including one or more of those described herein, may be used to assemble nanoscale wires on a surface. In some embodiments, the nanoscale wire may be positioned proximate the surface of a substrate, i.e., the nanoscale wire may be positioned within about 50 nm, about 25 nm, about 10 nm, or about 5 nm of the substrate. For example, another material, other than the substrate and nanowire, can separate the substrate from the nanowire. In some cases, the nanoscale wire may contact at least a portion of the substrate. Any substrate may be used for nanoscale wire placement, for example, a substrate comprising a semiconductor (e.g., Si, Ge, GaAs, etc.), a substrate comprising a metal, a substrate comprising a glass, a substrate comprising a polymer (e.g., polyethylene, polypropylene, poly(ethylene terephthalate), polydimethylsiloxane, or the like), a substrate comprising a gel, a substrate that is a thin film, a substantially transparent substrate, a non-planar substrate, a flexible substrate, a curved substrate, etc. Thus, in one set of embodiments a polymeric, flexible, and/or a glass substrate may be used.

In certain embodiments, the substrate may be a non-planar or a curved surface (i.e., a surface that can be characterized as having a radius of curvature). The substrate may also be a flexible substrate in some cases, i.e., a substrate able to bend or flex. For example, a flexible substrate may be bent or distorted by a volumetric displacement of at least about 5%, about 10%, or about 20% (relative to the undisturbed volume), without causing cracks and/or breakage of the substrate, i.e., the substrate can be distorted such that about 5%, about 10%, or about 20% of the mass of the substrate has been moved outside the original surface perimeter of the substrate. Non-limiting examples of flexible substrates include polymers, fibers, gels, etc. In some cases, the flexible substrate may be present in an article that is robust, for example, able to sustain typical use (e.g., being moved, carried, dropped, etc.). For example, the substrate may be included within a wearable article, for example, an article of clothing or an accessory.

In certain embodiments, the substrate may be at least partially transparent, and in some cases, substantially transparent. As used herein, a “substantially transparent” material is a material that allows electromagnetic radiation to be transmitted through the material without significant scattering, i.e., at least a portion of the radiation incident on the material passes through the material unaltered. In some cases, the material is substantially transparent to incident electromagnetic radiation ranging from the infrared to ultraviolet ranges (including visible light). The substantially transparent material may be able to transmit electromagnetic radiation in some cases such that at least a portion of the radiation incident on the material passes through the material unaltered, and in some embodiments, at least about 50%, in other embodiments at least about 75%, in other embodiments at least about 80%, in still other embodiments at least about 90%, in still other embodiments at least about 95%, in still other embodiments at least about 97%, and in still other embodiments at least about 99% of the incident radiation is able to pass through the material unaltered. Suitable non-limiting examples of transparent materials include glasses, certain polymers, etc.

One aspect of the invention involves the production of a nanoscale wire array, or other array involving nanostructured materials. In some cases, the array may be produced by providing a surface having a plurality of substantially aligned nanoscale wires, and removing, from the surface, a portion of the plurality of nanoscale wires. The remaining nanoscale wires on the surface may then be connected to one or more electrodes in some instances.

In one set of embodiments, any suitable technique may be used to produce a surface having a plurality of substantially aligned nanoscale wires. The surface may have any density of nanoscale wires thereon, for example, at least about 1 wire/micron², at least about 3 wires/micron², at least about 10 wires/micron², at least about 30 wires/micron², at least about 100 wires/micron², at least about 300 wires/micron², at least about 1000 wires/micron², at least about 3000 wires/micron², at least about 10,000 wires/micron², at least about 30,000 wires/micron 2, at least about 100,000 wires/micron², at least about 300,000 wires/micron², or more in some cases. In certain embodiments, the aligned nanoscopic wires may have a “pitch” (i.e., the spacing between the centers of adjacent nanoscale wires) of less than about 500 nm, less than about 200 nm, less than about 100 nm, less than about 50 nm, or less than about 20 nm in some cases. In other embodiments, the pitch of the nanowires may be at least about 100 nm, at least about 200 nm, at least about 300 nm, at least about 400 nm, at least about 500 nm, at least about 600 nm, at least about 750 nm, at least about 1 micrometer, at least about 2 micrometers, at least about 3 micrometers, at least about 5 micrometers, at least about 10 micrometers, at least about 15 micrometers, at least about 20 micrometers, or at least about 25 micrometers or greater. In certain embodiments, the aligned nanoscopic wires are arranged such that they are in contact with each other; in other embodiments, however, the aligned nanoscopic wires may be at a pitch such that they are substantially not in physical contact.

The aligned nanoscopic wires may be either grown in place or deposited after growth. Assembly, or controlled placement of nanoscopic wires on surfaces after growth may be performed by aligning nanoscopic wires using an electrical field, or other techniques such as those described below. An electrical field may be generated between electrodes. Thus, the nanoscopic wires may be positioned between the electrodes (optionally flowed into a region between the electrodes in a suspending fluid), and may align in the electrical field. As another example, nanoscale wires may be aligned by electrostatic or magnetic force between nanoscale wires. For instance, by introducing charge onto nanoscale wire surface, electrostatic forces between nanoscale wires can align them into certain patterns, such as in parallel arrays.

Nanoscale wires can also be assembled using a Langmuir-Blodgett (LB) trough. Nanoscale wires are first surface conditioned and dispersed to the surface of a liquid phase to form a Langmuir-Blodgett film. The liquid may be any liquid able to contain the nanoscale wires, e.g., in suspension. In some cases, the liquid may include a surfactant, which can, in some cases, reduce aggregation of the nanoscale wires and/or reduce the ability of the nanoscale wires to interact with each other. Non-limiting examples of suitable surfactants include alcohols and amines.

The nanoscale wires can then be aligned into different patterns (such as parallel arrays or fibers) by compressing the surface or reducing the surface area of the surface (for example, by narrowing the containing holding the fluid, draining part of the fluid, etc.). In one embodiment, the liquid is uniaxially compressed. As an example, the surface area of the fluid may be reduced in some fashion (thereby reducing the average distance between the nanoscale wires), for instance, such that at least some, or substantially all, of the nanoscale wires come into physical contact with each other; or such that the nanoscale wires do not come into substantial contact with each other, but are substantially regularly spaced or positioned, for instance, having a pitch such as those described above. The nanoscale wire patterns can then be transferred onto a desired substrate, which may be, for example, a semiconductor such as silicon, a polymer, a glass, a polymer, etc, as previously described.

In one aspect, a portion of the plurality of nanoscale wires are removed from the surface, e.g., so that the surface has a portion of the nanoscale wires placed on the surface. In some cases, the nanoscale wires can be removed from the surface while retaining substantial alignment of the nanoscale wires that remain on the surface.

In one embodiment, the nanoscale wires may be removed from the surface in a first pattern while leaving nanoscale wires on the surface in a second pattern complementary to the first pattern. In certain instances, the second pattern includes a plurality of ordered regions of nanoscale wires, where each region including nanoscale wires positioned relative to each other in a manner similar from region to region. In some instances, at least one region is defined (at least in part), by a boundary having a substantially straight portion perpendicular to the axis of the aligned nanoscale wires. In some cases, the surface is essentially free of nanoscale wires within about 5 nm of the boundary, and in some cases, the surface is essentially free of nanoscale wires within about 10 nm, about 30 nm, about 100 nm, about 300 nm, about 1 micron, about 3 micrometers, or about 10 micrometers or more of the boundary. In another embodiment, the nanoscale wires may be removed from the surface such that each of the plurality of first regions is isolated by a contiguous second region free of nanoscale wires.

The region free of nanoscale wires on the surface may be of any shape, and may be contiguous or noncontiguous. In some cases, a first region of the surface may be contiguous, and define one or multiple second regions of the surface having nanoscale wires disposed thereon. The second regions may be of any size or shape, including square, triangular, rectilinear, circular, ovoid and arbitrary shapes, etc. In some cases, the first region may have a shape for use within an electrical device, i.e., the first region forms a circuit, or part of a circuit, for an electrical device. In other cases, the first region may have a shape that is substantially defined by substantially right angles, which includes squares and rectangles, “T” shapes, “L” shapes, “H” shapes, as well as more complicated shapes. The first and second regions on the surface, in certain instances, may form a grid pattern or other regularly repeating or tiling pattern, for example, as shown in FIG. 10B. In some cases, each of the first regions may be separated by a distance of at least about 5 nm, at least about 10 nm, at least about 25 nm, at least about 50 nm, at least about 100 nm, at least about 250 nm, at least about 500 nm, at least about 750 nm, at least about 1 micron, at least about 3 micrometers, at least about 10 micrometers, at least about 30 micrometers, at least about 100 micrometers, etc.

Any suitable technique may be used to remove the portion of the plurality of nanoscale wires from the surface, for example, but not limited to, etching, reactive ion etching, sonication, electron beam lithography methods or other conventional lithographic techniques. In some cases, the removal may be done anisotropically, e.g., a portion of a nanoscale wire(s) is removed such that the wire is not radially symmetric. Those of ordinary skill in the art will know of other suitable techniques to remove nanoscale wires from a portion of surface.

One or more electrodes may be connected to the nanoscale wires on the surface in some embodiments of the invention, using any suitable technique. In some cases, the electrodes may be connected to the nanoscale wires in a stochastic fashion, i.e., a substantial number of connections are made between nanoscale wires and electrodes, without necessarily requiring each individual nanoscale wire and each electrode. For example, at least about 50%, at least about 60%, at least about 70%, at least about 80%, or at least about 90% of the nanoscale wires on a surface may be connected to an electrode. Examples of techniques suitable for connecting electrodes to nanoscale wires can be found in Ser. No. 10/627,405, entitled “Stochastic Assembly of Sublithographic Nanoscale Interfaces,” filed Jul. 24, 2003, incorporated herein by reference.

The electrodes may have any shape such that electrical communication is able to occur between one or more nanoscale wires and other electronics on the micrometer scale (e.g., a microelectronic or a semiconductor chip), and/or on the macro scale. For example, one or more electrodes may have a series of contact points, in which an electronic circuit can be placed into electronic communication with one or more nanoscale wires within a nanoscale wire array. In one embodiment, the electrode is interdigitated. For example, the electrode may have a series of discrete indentations where an electrical connection may be made.

In some embodiments, the nanoscopic wire (or other nanostructured material) may include additional materials, such as semiconductor materials, dopants, organic compounds, inorganic compounds, etc. The following are non-limiting examples of materials that may be used as dopants. The dopant may be an elemental semiconductor, for example, silicon, germanium, tin, selenium, tellurium, boron, diamond, or phosphorous. The dopant may also be a solid solution of various elemental semiconductors. Examples include a mixture of boron and carbon, a mixture of boron and P(BP₆), a mixture of boron and silicon, a mixture of silicon and carbon, a mixture of silicon and germanium, a mixture of silicon and tin, a mixture of germanium and tin, etc. In some embodiments, the dopant may include mixtures of Group IV elements, for example, a mixture of silicon and carbon, or a mixture of silicon and germanium. In other embodiments, the dopant may include mixtures of Group III and Group V elements, for example, BN, BP, BAs, AlN, AlP, AlAs, AlSb, GaN, GaP, GaAs, GaSb, InN, InP, InAs, or InSb. Mixtures of these combinations may also be used, for example, a mixture of BN/BP/BAs, or BN/AlP. In other embodiments, the dopants may include mixtures of Group III and Group V elements. For example, the mixtures may include AlGaN, GaPAs, InPAs, GaInN, AlGaInN, GaInAsP, or the like. In other embodiments, the dopants may also include mixtures of Group II and Group VI elements. For example, the dopant may include mixtures of ZnO, ZnS, ZnSe, ZnTe, CdS, CdSe, CdTe, HgS, HgSe, HgTe, BeS, BeSe, BeTe, MgS, MgSe, or the like. Alloys or mixtures of these dopants are also be possible, for example, ZnCd Se, or ZnSSe or the like. Additionally, mixtures of different groups of semiconductors may also be possible, for example, combinations of Group II-Group VI and Group III-Group V elements, such as (GaAs)ₓ(ZnS)₁₋ₓ. Other non-limiting examples of dopants may include mixtures of Group IV and Group VI elements, for example GeS, GeSe, GeTe, SnS, SnSe, SnTe, PbO, PbS, PbSe, PbTe, etc. Other dopant mixtures may include mixtures of Group I elements and Group VII elements, such as CuF, CuCl, CuBr, CuI, AgF, AgCl, AgBr, AgI, or the like. Other dopant mixtures may include different mixtures of these elements, such as BeSiN₂, CaCN₂, ZnGeP₂, CdSnAs₂, ZnSnSb₂, CuGeP₃, CuSi₂P₃, Si₃N₄, Ge₃N₄, Al₂O₃, (Al, Ga, In)₂(S, Se, Te)₃, Al₂CO, (Cu, Ag)(Al, Ga, In, Tl, Fe)(S, Se, Te)₂ or the like. As a particular non-limiting example, a p-type dopant may be selected from Group III, and an n-type dopant may be selected from Group V. For instance, a p-type dopant may include at least one of B, Al and In, and an n-type dopant may include at least one of P, As and Sb. For Group III-Group V mixtures, a p-type dopant may be selected from Group II, including one or more of Mg, Zn, Cd and Hg, or Group IV, including one or more of C and Si. An n-type dopant may be selected from at least one of Si, Ge, Sn, S, Se, and Te. It will be understood that the invention is not limited to these dopants, but may include other elements, alloys, or mixtures as well.

The nanoscale wire of the present invention may further include, in some cases, any organic or inorganic molecules. In some cases, the organic or inorganic molecules are polarizable and/or have multiple charge states. For example, the nanoscale wires may include gallium arsenide, gallium nitride, indium phosphide, germanium, or cadmium selenide.

In yet another set of embodiments, the nanoscale wire (or other nanostructured material) may comprise two or more regions having different compositions. Each region of the nanoscale wire may have any shape or dimension, and these can be the same or different between regions. For example, a region may have a smallest dimension of less than about 1 micrometer, less than about 100 nm, less than about 10 nm, or less than about 1 nm. In some cases, one or more regions may be a single monolayer of atoms (i.e., “delta-doping”). In certain cases, the region may be less than a single monolayer thick (for example, if some of the atoms within the monolayer are absent).

The two or more regions may be longitudinally arranged relative to each other, and/or radially arranged (e.g., as in a core/shell arrangement) within the nanoscale wire. As one example, the nanoscale wire may have multiple regions of semiconductor materials arranged longitudinally. In another example, a nanoscale wire may have two regions having different compositions arranged longitudinally, surrounded by a third region or several regions, each having a composition different from that of the other regions. As another example, the nanoscale wire may have a series of regions positioned both longitudinally and radially relative to each other. The arrangement can include a core that differs in composition along its length (changes in composition or concentration longitudinally), while the lateral (radial) dimensions of the core do, or do not, change over the portion of the length differing in composition. The shell portions can be adjacent each other (contacting each other, or defining a change in composition or concentration of a unitary shell structure longitudinally), or can be separated from each other by, for example, air, an insulator, a fluid, or an auxiliary, non-nanoscale wire component. Thus, the invention also allows the provision of any combination of a nanowire core and any number of radially-positioned shells (e.g., concentric shells), where the core and/or any shells can vary in composition and/or concentration longitudinally, any shell sections can be spaced from any other shell sections longitudinally, and different numbers of shells can be provided at different locations longitudinally along the structure. More than two regions may be present within the nanoscale wire, and these regions may have unique compositions, or may comprise the same compositions.

Suitable techniques for fabricating nanoscale wires (or other nanostructured materials) include, but are not limited, to the following. Certain embodiments of the invention may utilize metal-catalyzed CVD techniques (“chemical vapor deposition”) to synthesize individual nanoscale wires. CVD synthetic procedures needed to prepare individual wires directly on surfaces and in bulk form are generally known, and can readily be carried out by those of ordinary skill in the art. Nanoscopic wires may also be grown through laser catalytic growth. With same basic principles as LCG, if uniform diameter nanoclusters (less than 10%-20% variation depending on how uniform the nanoclusters are) are used as the catalytic cluster, nanoscale wires with uniform size (diameter) distribution can be produced, where the diameter of the nanoscale wires is determined by the size of the catalytic clusters. By controlling the growth time, nanoscale wires with different lengths can be grown.

One technique that may be used to grow nanoscale wires is catalytic chemical vapor deposition (“C-CVD”). In the C-CVD method, the reactant molecules (e.g., silane and the dopant) are formed from the vapor phase, as opposed to from laser vaporization. In C-CVD, nanoscale wires may be doped by introducing the doping element into the vapor phase reactant (e.g. diborane and phosphane for p-type and n-type doped regions). The doping concentration may be controlled by controlling the relative amount of the doping compound introduced in the composite target. The final doping concentration or ratios are not necessarily the same as the vapor-phase concentration or ratios. By controlling growth conditions, such as temperature, pressure or the like, nanoscale wires having the same doping concentration may be produced. To produce a nanoscale wire having adjacent regions having different compositions within a nanoscale wire, the doping concentration may be varied by simply varying the ratio of gas reactant (e.g. from about 1 ppm to about 10%, from about 10 ppm to about 20%, from about 100 ppm to about 50%, or the like), or the types of gas reactants used may be altered during growth of the nanoscale wire. The gas reactant ratio or the type of gas reactants used may be altered several times during growth of the nanoscale wire, which may produce nanoscale wires comprising regions having multiple compositions, all of which may or may not be unique.

Another technique for direct fabrication of nanoscale wire junctions during synthesis is generally referred to as laser catalytic growth (“LCG”). In laser catalytic growth, dopants are controllably introduced during vapor phase growth of nanoscale wires. Laser vaporization of a composite target composed of a desired material (e.g. silicon or indium phosphide) and a catalytic material (e.g. a nanoparticle catalyst) may create a hot, dense vapor. The vapor may condenses into liquid nanoclusters through collision with a buffer gas. Growth may begin when the liquid nanoclusters become supersaturated with the desired phase and can continue as long as reactant is available. Growth may terminate when the nanoscale wire passes out of the hot reaction zone or when the temperature is decreased. The nanoscale wire may be further subjected to different semiconductor reagents during growth. The catalytic materials and/or the vapor phase reactants may be produced by any suitable technique. For example, laser ablation techniques may be used to generate catalytic clusters or vapor phase reactant that may be used during LCG. Other techniques are also contemplated, such as thermal evaporation techniques. The laser ablation technique may generate liquid nanoclusters that may subsequently define the size and direct the growth direction of the nanoscopic wires. The diameters of the resulting nanoscale wires may be determined by the size of the catalyst cluster. Further diameter control may be achieved by using uniform diameter catalytic clusters. As an example, vapor phase semiconductor reactants required for nanoscale wire growth may be produced by laser ablation of solid targets, vapor-phase molecular species, or the like. Any catalyst able to catalyze the production of nanoscale wires may be used. Gold may be preferred in certain embodiments. A wide range of other materials may also be contemplated, for example, a transition metal such as silver, copper, zinc, cadmium, iron, nickel, cobalt, and the like.

Other techniques to produce nanoscale semiconductors such as nanoscale wires are also within the scope of the present invention. For example, nanoscale wires of any of a variety of materials may be grown directly from vapor phase through a vapor-solid process. Also, nanoscale wires may also be produced by deposition on the edge of surface steps, or other types of patterned surfaces. Further, nanoscale wires may be grown by vapor deposition in or on any generally elongated template. The porous membrane may be porous silicon, anodic alumnia, a diblock copolymer, or any other similar structure. The natural fiber may be DNA molecules, protein molecules carbon nanotubes, any other elongated structures. For all the above described techniques, the source materials may be a solution or a vapor. In some embodiments, while in solution phase, the template may also include be column micelles formed by surfactant molecules in addition to the templates described above.

For a doped semiconductor, the semiconductor may be doped before and/or during growth of the semiconductor. Doping the semiconductor during growth may result in the property that the doped semiconductor is bulk-doped. Further, such doped semiconductors may be controllably doped, such that a concentration of a dopant within the doped semiconductor can be controlled and therefore reproduced consistently, making possible the commercial production of such semiconductors. See, e.g., Ser. No. 09/935,776, entitled “Doped Elongated Semiconductors, Growing Such Semiconductors, Devices Including Such Semiconductors, and Fabricating Such Devices,” filed Aug. 22, 2001, published as Publication No. 2002/0130311 on Sep. 19, 2002, incorporated herein by reference.

In one technique of post-synthetic doping of nanoscale wires (or other nanostructured material), a nanoscale wire having a substantially homogeneous composition is first synthesized, then is doped post-synthetically with various dopants. For example, a p/n junction can be created by introducing p-type and an n-type dopants down onto a single nanoscale wire. The p/n junction can then be further annealed to allow the dopants to migrate further into the nanoscale wire to form a bulk-doped nanoscale wire.

Other techniques for assembling nanoscale wires on a surface include, but are not limited to, the following. In one embodiment, an electric field may be generated between individual contact points that will attract a single nanoscopic wire to span the distance between the points, forming a pathway for electronic communication between the points. Thus, individual nanoscopic wires may be assembled between individual pairs of electrical contacts. Electrodes, or contact points, may be fabricated via any suitable microfabrication techniques, such as the ones described herein. In another embodiment, a positioning arrangement involving positioning a fluid flow directing apparatus to direct a fluid that may contain suspended nanoscopic wires toward and in the direction of alignment with locations at which nanoscale wires are desirably positioned.

Another arrangement involves forming surfaces including regions that selectively attract nanoscale wires surrounded by regions that do not selectively attract them. For example, —NH₂ can be presented in a particular pattern at a surface, and that pattern will attract nanoscale wires or nanotubes having surface functionality attractive to amines. Surfaces can be patterned using known techniques such as electron-beam patterning, “soft-lithography” have been previously described. Fluid flow channels can be created at a size scale advantageous for placement of nanoscale wires on surfaces using a variety of techniques known to those of ordinary skill in the art. For example, one such technique for creating a fluid flow channel is to use a polydimethylsiloxane mold. Channels may be created and applied to a surface, and a mold may be removed and re-applied in a different orientation to provide a cross flow arrangement or different arrangement. The flow channel arrangement can include channels having a smallest width of less than about 1 mm, preferably less than about 0.5 mm, more preferably less than about 200 micrometers, or less. Such channels are easily made by fabricating a master by using photolithography and casting PDMS on the master, as described in the above-referenced patent applications and international publications. Larger-scale assembly may be possible as well. The area that can be patterned with nanoscale wire arrays may be defined only by the feature of the channel which can be as large as desired.

The assembly of nanoscale wires onto substrate and electrodes may also be assisted using bimolecular recognition in certain embodiments, for example, by immobilizing one biological binding partner on a nanoscale wire surface and the other one on substrate or electrodes using physical adsorption or covalently linking. Bio-recognition techniques suitable for use in the present invention may include DNA hybridization, antibody-antigen binding, biotin-avidin, biotin-streptavidin binding, and the like.

Another technique which may be used to direct the assembly of a nanoscopic wires into a device is by using “SAMs,” or self-assembled monolayers. The SAMs may be chemically patterned in certain embodiments. In one example of patterning SAMs for directed assembly of nanoscopic scale circuitry using nanoscopic wires of the present invention, atomic force microscopy (AFM) may be used to write, at high resolution, a pattern in a SAM, after which the SAM may then be removed.

In another embodiment, microcontact printing may be used to apply patterned SAMs to a substrate. Open areas in the patterned surface (i.e., the SAM-free linear region between linear SAM) may be filled, for example, with an amino-terminated SAM that may interact in a highly specific manner with a nanoscopic wire. The result may be a patterned SAM, on a substrate, that includes linear SAM portions separated by amino-terminated SAM material. Any desired pattern may be formed where regions of the amino-terminated SAM material corresponds to regions at which wire deposition may be desired. The patterned surface may then be dipped into a suspension of nanoscopic wires, and may be rinsed to create an array of nanoscale wires.

Nanoscale wires (or any other nanostructured materials) can also be aligned by inducing a flow of nanoscale wire solution on surface, in other embodiments of the invention. Nanoscale wire arrays with controlled position and periodicity can be produced by patterning a surface of a substrate and/or conditioning the surface of the nanoscale wires with different functionalities, where the position and periodicity control is achieved by designing specific complementary forces (chemical or biological or electrostatic or magnetic or optical) between the patterned surface and wires. For example, wire A goes to patterned area A′, wire B goes to patterned area B′, wire C goes to patterned area C′, and every other wire goes to its respective patterned area. The surface of the substrate and/or nanoscale wires can be conditioned with different molecules/materials, or different charges, different magnetos or different light intensities (e.g., interference/diffraction patterns from light beams) or any combination of these.

Nanoscale wire arrays can also be transferred to another substrate, e.g., by stamping, in certain embodiments. Nanoscale wires can be assembled by complementary interaction. Flow can be used for assembly of nanoscale wires in the above methods, although it is not limited to flow only. Complementary chemical, biological, electrostatic, magnetic or optical interactions alone can also be exploited for nanoscale wire assembly (although with less control). Nanoscale wires can be assembled using physical patterns. For instance, nanoscale wire solutions can be deposited onto substrate with physical patterns, such as surface steps, trenches and others. Nanoscale wires can also be aligned along the corner of the surface steps or along the trenches.

The present invention also contemplates a wide variety of devices in certain aspects. Such devices may include electrical devices, optical devices, optronic devices, spintronic devices, mechanical devices or any combination thereof, for example, optoelectronic devices or electromechanical devices. Functional devices assembled from the nanoscale wires (or other nanostructured materials) described herein may be used to produce various computer or device architectures. For example, certain nanoscale wires described herein may be assembled into nanoscale versions of conventional semiconductor devices, such as diodes, Zener diodes, tunnel diodes, light emitting diodes (LEDs), inverters, sensors, field effect transistors (“FET”), bipolar junction transistors (“BJT”), etc. These devices may include single, free-standing nanoscale wires, crossed nanoscale wires, or combinations of single nanoscale wires combined with other components. The nanoscale wires, in particular cases, may also have multiple regions, each of which may have different compositions, as previously described.

In some cases, a nanoscale memory switching device may be assembled from one or more nanoscale wires described herein. The memory switching device may have multiple states, non-volatile reversible states, and/or a large on/off ratio in some instances. The nanoscale memory switching devices may be highly parallel and scalable with simple chemical assembly process, and can be useful in construction of a chemically assemble computer in some embodiments.

Certain embodiments of the invention involve a sensing element. The sensing element may be an electronic sensing element, and the sensing element may include a nanoscale wire able to detect the presence, absence, and/or amount (concentration), of a species such as an analyte in a sample (e.g. a fluid sample) containing, or suspected of containing, the species. Also provided, according to certain embodiments, is an article comprising a nanoscale wire and a detector constructed and arranged to determine a change in an electrical property of the nanoscale wire. In certain embodiments, the sensing element is an element able to detect stress, i.e., forces on the sensing element that cause the sensing element to register and/or have at least one physical and/or chemical property that changes with exposure to mechanical stresses. The forces applied on the sensing element can include, but are not limited to, electrical forces, mechanical forces, magnetic forces, chemical forces, etc. In some cases, the force applied to the sensing element originates from non-mechanical sources. For example, an electrical or a magnetic force may be applied to a nanoscale wire that is susceptible to the electrical or magnetic force, and such force may be determined as a change in mechanical stress on the nanoscale wire. In certain embodiments, the sensing element comprises a nanoscale wire or other nanostructure. As an example, if the sensing element is positioned proximate a surface of a substrate, e.g., a flexible substrate, stresses on and/or distortions of the substrate may be determined by or using the sensing element, for example, by changes in voltage, conductivity, resistivity, etc., of the sensing element. Thus, as a particular example, a sensing element proximate a surface of a substrate may be responsive to changes in the radius of curvature of a substrate. In some cases, more than one sensing element may be present. For instance, multiple sensing elements may be used to determine directional stresses on the substrate.

As previously discussed, one aspect of the present invention includes the ability to fabricate essentially any electronic device in an array. This includes any device that can be made in accordance with this aspect of the invention that one of ordinary skill in the art would desirably make. Examples of such devices include, but are not limited to, arrays including one or more of: field effect transistors (FETs), bipolar junction transistors (BJTs), tunnel diodes, modulation doped superlattices, complementary inverters, light emitting devices, light sensing devices, biological system imagers, biological and chemical detectors or sensors, thermal or temperature detectors, Josephine junctions, nanoscale light sources, photodetectors such as polarization-sensitive photodetectors, gates, inverters, AND, NAND, NOT, OR and NOR gates, latches, flip-flops, registers, switches, clock circuitry, static or dynamic memory devices and arrays, state machines, gate arrays, and any other dynamic or sequential logic or other digital devices including programmable circuits. Also included are analog devices and circuitry, including but not limited to, amplifiers, switches and other analog circuitry using active transistor devices, as well as mixed signal devices and signal processing circuitry. Also included are p/n junction devices with low turn-on voltages; p/n junction devices with high turn-on voltages; and computational devices such as a half-adder. Furthermore, junctions within the array having large dielectric contrasts between the two regions may be used to produce 1 D waveguides with built-in photonic band gaps, or cavities for nanoscale wire lasers. In some embodiments, the nanoscale wires within the array may be manufactured during the device fabrication process. In other embodiments, the nanoscale wires within the array may first be synthesized, then assembled.

Additionally, one aspect of the present invention includes an array where the components are pre-fabricated (i.e., doped, in individual and separate processes with components separate from each other when doped) and then brought into contact after doping. In other cases, n-type and p-type semiconductors, initially in non-contacting arrangement, may be brought into contact with each other to form an array. Essentially any device can be made in accordance with this aspect of the invention that one of ordinary skill in the art would desirably make.

One embodiment of the invention allows a two-dimensional memory element density of at least about 10¹¹ memory elements/cm², at least about 10¹² memory elements/cm², or at least about 10¹³ memory elements/cm², using the arrays of the invention. For example, by using nanotubes that are about 10 micrometers in length, with a memory element every 20 nm along each nanotube, an array can be formed with 500 parallel wires in each direction, each wire containing 500 crossbar array junctions (memory elements). 250,000 or more memory elements can be formed in such an array. Three-dimensional arrays can be created as well. Where a 1 micrometer spacing is created between two-dimensional array planes, the invention provides a three-dimensional array density of at least about 10¹⁴ memory elements/cm³, at least about 10¹⁵ memory elements/cm³, or at least about 10¹⁶ memory elements/cm³.

Definitions

The following definitions will aid in the understanding of the invention. Certain devices of the invention may include wires or other components of scale commensurate with nanometer-scale wires, which includes nanotubes and nanowires. In some embodiments, however, the invention comprises articles that may be greater than nanometer size (e.g., micrometer-sized). As used herein, “nanoscopic-scale,” “nanoscopic,” “nanometer-scale,” “nanoscale,” the “nano-” prefix (for example, as in “nanostructured”), and the like generally refers to elements or articles having widths or diameters of less than about 1 micrometer, and less than about 100 nm in some cases. In all embodiments, specified widths can be a smallest width (i.e. a width as specified where, at that location, the article can have a larger width in a different dimension), or a largest width (i.e. where, at that location, the article has a width that is no wider than as specified, but can have a length that is greater).

The term “plurality,” as used herein, means two or more. A “set” of items may include one or more of such items.

The term “fluid” generally refers to a substance that tends to flow and to conform to the outline of its container. Typically, fluids are materials that are unable to withstand a static shear stress. When a shear stress is applied to a fluid, it experiences a continuing and permanent distortion. Typical fluids include liquids and gases, but may also include free-flowing solid particles, viscoelastic fluids, and the like.

As used herein, a “wire” generally refers to any material having a conductivity of or of similar magnitude to any semiconductor or any metal, and in some embodiments may be used to connect two electronic components such that they are in electronic communication with each other. For example, the terms “electrically conductive” or a “conductor” or an “electrical conductor” when used with reference to a “conducting” wire or a nanoscale wire, refers to the ability of that wire to pass charge. Typically, an electrically conductive nanoscale wire will have a resistivity comparable to that of metal or semiconductor materials, and in some cases, the electrically conductive nanoscale wire may have lower resistivities, for example, a resistivity lower than about 10⁻³ Ohm m, lower than about 10⁻⁴ Ohm m, or lower than about 10⁻⁶ Ohm m or 10⁻⁷ Ohm m.

A “nanoscopic wire” (also known herein as a “nanoscopic-scale wire” or “nanoscale wire”) generally is a wire, that at any point along its length, has at least one cross-sectional dimension and, in some embodiments, two orthogonal cross-sectional dimensions less than 1 micron, less than about 500 nm, less than about 200 nm, less than about 150 nm, less than about 100 nm, less than about 70, less than about 50 nm, less than about 20 nm, less than about 10 nm, or less than about 5 nm. In other embodiments, the cross-sectional dimension can be less than 2 nm or 1 nm. In one set of embodiments, the nanoscale wire has at least one cross-sectional dimension ranging from 0.5 nm to 100 nm or 200 nm. In some cases, the nanoscale wire is electrically conductive. Where nanoscale wires are described having, for example, a core and an outer region, the above dimensions generally relate to those of the core. The cross-section of a nanoscopic wire may be of any arbitrary shape, including, but not limited to, circular, square, rectangular, annular, polygonal, or elliptical, and may be a regular or an irregular shape. The nanoscale wire may be solid or hollow. Any nanoscale wire can be used in any of the embodiments described herein, including carbon nanotubes, molecular wires (i.e., wires formed of a single molecule), nanorods, nanowires, nanowhiskers, organic or inorganic conductive or semiconducting polymers, and the like, unless otherwise specified. Other conductive or semiconducting elements that may not be molecular wires, but are of various small nanoscopic-scale dimensions, can also be used in some instances, e.g. inorganic structures such as main group and metal atom-based wire-like silicon, transition metal-containing wires, gallium arsenide, gallium nitride, indium phosphide, germanium, cadmium selenide, etc. A wide variety of these and other nanoscale wires can be grown on and/or applied to surfaces in patterns useful for electronic devices in a manner similar to techniques described herein involving the specific nanoscale wires used as examples, without undue experimentation. The nanoscale wires, in some cases, may be formed having dimensions of at least about 1 micrometer, at least about 3 micrometers, at least about 5 micrometers, or at least about 10 micrometers or about 20 micrometers in length, and can be less than about 100 nm, less than about 80 nm, less than about 60 nm, less than about 40 nm, less than about 20 nm, less than about 10 nm, or less than about 5 nm in thickness (height and width). The nanoscale wires may have an aspect ratio (length to thickness) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

A “nanowire” (e.g. comprising silicon and/or another semiconductor material) is a nanoscopic wire that is typically a solid wire, and may be elongated in some cases. Preferably, a nanowire (which is abbreviated herein as “NW”) is an elongated semiconductor, i.e., a nanoscale semiconductor. A “non-nanotube nanowire” is any nanowire that is not a nanotube. In one set of embodiments of the invention, a non-nanotube nanowire having an unmodified surface can be used in any arrangement of the invention described herein in which a nanowire or nanotube can be used.

As used herein, a “nanotube” (e.g. a carbon nanotube) is a nanoscopic wire that is hollow, or that has a hollowed-out core, including those nanotubes known to those of ordinary skill in the art. “Nanotube” is abbreviated herein as “NT.” Nanotubes are used as one example of small wires for use in the invention and, in certain embodiments, devices of the invention include wires of scale commensurate with nanotubes.

As used herein, an “elongated” article (e.g. a semiconductor or a section thereof) is an article for which, at any point along the longitudinal axis of the article, the ratio of the length of the article to the largest width at that point is greater than 2:1.

As used herein, a “width” of an article is the distance of a straight line from a point on a perimeter of the article, through the center of the article, to another point on the perimeter of the article. As used herein, a “width” or a “cross-sectional dimension” at a point along a longitudinal axis of an article is the distance along a straight line that passes through the center of a cross-section of the article at that point and connects two points on the perimeter of the cross-section. The “cross-section” at a point along the longitudinal axis of an article is a plane at that point that crosses the article and is orthogonal to the longitudinal axis of the article. The “longitudinal axis” of an article is the axis along the largest dimension of the article. Similarly, a “longitudinal section” of an article is a portion of the article along the longitudinal axis of the article that can have any length greater than zero and less than or equal to the length of the article. Additionally, the “length” of an elongated article is a distance along the longitudinal axis from end to end of the article.

As used herein, a “cylindrical” article is an article having an exterior shaped like a cylinder, but does not define or reflect any properties regarding the interior of the article. In other words, a cylindrical article may have a solid interior, may have a hollowed-out interior, etc. Generally, a cross-section of a cylindrical article appears to be circular or approximately circular, but other cross-sectional shapes are also possible, such as a hexagonal shape. The cross-section may have any arbitrary shape, including, but not limited to, square, rectangular, or elliptical. Regular and irregular shapes are also included.

As used herein, an “array” of articles (e.g., nanoscopic wires) comprises a plurality of the articles, for example, a series of aligned nanoscale wires, which may or may not be in contact with each other. As used herein, a “crossed array” or a “crossbar array” is an array where at least one of the articles contacts either another of the articles or a signal node (e.g., an electrode).

Many nanoscopic wires as used in accordance with the present invention are individual nanoscopic wires. As used herein, “individual nanoscopic wire” means a nanoscopic wire free of contact with another nanoscopic wire (but not excluding contact of a type that may be desired between individual nanoscopic wires, e.g., as in a crossbar array). For example, an “individual” or a “free-standing” article may, at some point in its life, not be attached to another article, for example, with another nanoscopic wire, or the free-standing article may be in solution. This is in contrast to nanotubes produced primarily by laser vaporization techniques that produce materials formed as ropes having diameters of about 2 nm to about 50 nm or more and containing many individual nanotubes (see, for example, Thess, et al., “Crystalline Ropes of Metallic Carbon Nanotubes,” Science, 273:483-486 (1996)). This is also in contrast to conductive portions of articles which differ from surrounding material only by having been altered chemically or physically, in situ, i.e., where a portion of a uniform article is made different from its surroundings by selective doping, etching, etc. An “individual” or a “free-standing” article is one that can be (but need not be) removed from the location where it is made, as an individual article, and transported to a different location and combined with different components to make a functional device such as those described herein and those that would be contemplated by those of ordinary skill in the art upon reading this disclosure.

In some embodiments, at least a portion of a nanoscopic wire may be a bulk-doped semiconductor. As used herein, a “bulk-doped” article (e.g. an article, or a section or region of an article) is an article for which a dopant is incorporated substantially throughout the crystalline lattice of the article, as opposed to an article in which a dopant is only incorporated in particular regions of the crystal lattice at the atomic scale, for example, only on the surface or exterior. For example, some articles such as carbon nanotubes are typically doped after the base material is grown, and thus the dopant only extends a finite distance from the surface or exterior into the interior of the crystalline lattice. It should be understood that “bulk-doped” does not define or reflect a concentration or amount of doping in a semiconductor, nor does it necessarily indicate that the doping is uniform. In particular, in some embodiments, a bulk-doped semiconductor may comprise two or more bulk-doped regions. Thus, as used herein to describe nanoscopic wires, “doped” refers to bulk-doped nanoscopic wires, and, accordingly, a “doped nanoscopic (or nanoscale) wire” is a bulk-doped nanoscopic wire. “Heavily doped” and “lightly doped” are terms the meanings of which are clearly understood by those of ordinary skill in the art.

As used herein, the term “Group,” with reference to the Periodic Table, is given its usual definition as understood by one of ordinary skill in the art. For instance, the Group II elements include Mg and Ca, as well as the Group II transition elements, such as Zn, Cd, and Hg. Similarly, the Group III elements include B, Al, Ga, In and Tl; the Group IV elements include C, Si, Ge, Sn, and Pb; the Group V elements include N, P, As, Sb and Bi; and the Group VI elements include O, S, Se, Te and Po. Combinations involving more than one element from each Group are also possible. For example, a Group II-VI material may include at least one element from Group II and at least one element from Group VI, for example, ZnS, ZnSe, ZnSSe, ZnCdS, CdS, or CdSe. Similarly, a Group III-V material may include at least one element from Group III and at least one element from Group V, for example GaAs, GaP, GaAsP, InAs, InP, AlGaAs, or InAsP. Other dopants may also be included with these materials and combinations thereof, for example, transition metals such as Fe, Co, Te, Au, and the like.

As used herein, a “semiconductor” is given its ordinary meaning in the art, i.e., an element having semiconductive or semi-metallic properties (i.e., between metallic and non-metallic properties). An example of a semiconductor is silicon. Other non-limiting examples include gallium, germanium, diamond (carbon), tin, selenium, tellurium, boron, or phosphorous.

As used herein, a “single crystal” item (e.g., a semiconductor) is an item that has covalent bonding, ionic bonding, or a combination thereof throughout the item. Such a single crystal item may include defects in the crystal, but is distinguished from an item that includes one or more crystals, not ionically or covalently bonded, but merely in close proximity to one another.

The following U.S. provisional and utility patent application documents are incorporated herein by reference in their entirety for all purposes: Ser. No. 60/142,216, entitled “Molecular Wire-Based Devices and Methods of Their Manufacture,” filed Jul. 2, 1999; Ser. No. 60/226,835, entitled, “Semiconductor Nanowires,” filed Aug. 22, 2000; Ser. No. 10/033,369, entitled “Nanoscopic Wire-Based Devices and Arrays,” filed Oct. 24, 2001, published as Publication No 2002/0130353 on Sep. 19, 2002; Ser. No. 60/254,745, entitled, “Nanowire and Nanotube Nanosensors,” filed Dec. 11, 2000; Ser. No. 60/292,035, entitled “Nanowire and Nanotube Nanosensors,” filed May 18, 2001; Ser. No. 60/292,121, entitled, “Semiconductor Nanowires,” filed May 18, 2001; Ser. No. 60/292,045, entitled “Nanowire Electronic Devices Including Memory and Switching Devices,” filed May 18, 2001; Ser. No. 60/291,896, entitled “Nanowire Devices Including Emissive Elements and Sensors,” filed May 18, 2001; Ser. No. 09/935,776, entitled “Doped Elongated Semiconductors, Growing Such Semiconductors, Devices Including Such Semiconductors, and Fabricating Such Devices,” filed Aug. 22, 2001, published as Publication No. 2002/0130311 on Sep. 19, 2002; Ser. No. 10/020,004, entitled “Nanosensors,” filed Dec. 11, 2001, published as Publication No. 2002/0117659 on Aug. 29, 2002; Ser. No. 60/348,313, entitled “Transistors, Diodes, Logic Gates and Other Devices Assembled from Nanowire Building Blocks,” filed Nov. 9, 2001; Ser. No. 60/354,642, entitled “Nanowire Devices Including Emissive Elements and Sensors,” filed Feb. 6, 2002; Ser. No. 10/152,490, entitled, “Nanoscale Wires and Related Devices,” filed May 20, 2002; Ser. No. 10/196,337, entitled, “Nanoscale Wires and Related Devices,” filed Jul. 16, 2002, published as Publication No. 2003/0089899 on May 15, 2003; Ser. No. 60/397,121, entitled “Nanowire Coherent Optical Components,” filed Jul. 19, 2002; Ser. No. 10/624,135, entitled “Nanowire Coherent Optical Components,” filed Jul. 21, 2003; Ser. No. 60/524,301, entitled, “Nanoscale Arrays and Related Devices,” filed Nov. 20, 2003; Ser. No. 60/397,121, entitled “Nanowire Coherent Optical Components,” filed Dec. 11, 2003; Ser. No. 60/544,800, entitled “Nanostructures Containing Metal-Semiconductor Compounds,” filed Feb. 13, 2004; Ser. No. 10/347,121, entitled, “Array-Based Architecture for Molecular Electronics,” filed Jan. 17, 2003; Ser. No. 10/627,405, entitled “Stochastic Assembly of Sublithographic Nanoscale Interfaces,” filed Jul. 24, 2003; Ser. No. 10/627,406, entitled “Sublithographic Nanoscale Memory Architecture,” filed Jul. 24, 2003; Ser. No. 60/524,301, entitled “Nanoscale Arrays and Related Devices,” filed Nov. 20, 2003; and Ser. No. 60/551,634, entitled “Robust Nanostructures,” filed Mar. 8, 2004. The following International Patent Publication is incorporated herein by reference in their entirety for all purposes: Application Serial No. PCT/JUS00/18138, entitled “Nanoscopic Wire-Based Devices, Arrays, and Methods of Their Manufacture,” filed Jun. 30, 2000, published as Publication No. WO 01/03208 on Jan. 11, 2001; Application Serial No. PCT/US01/26298, entitled “Doped Elongated Semiconductors, Growing Such Semiconductors, Devices Including Such Semiconductors, and Fabricating Such Devices,” filed Aug. 22, 2001, published as Publication No. WO 02/17362 on Feb. 28, 2002; Application Serial No. PCT/US01/48230, entitled “Nanosensors,” filed Dec. 11, 2001, published as Publication No. WO 02/48701 on Jun. 20, 2002; Application Serial No. PCT/US02/16133, entitled “Nanoscale Wires and Related Devices,” filed May 20, 2002, published as Publication No. WO 03/005450 on Jan. 16, 2003.

The following examples are intended to illustrate certain embodiments of the present invention, but do not exemplify the full scope of the invention.

### EXAMPLE 1

The merger of nanoscale devices with flexible plastics or polymers enables a broad spectrum of electronic and photonic applications. In this example, the use of room temperature nanoimprint lithography for the general fabrication of nanometer- through millimeter-scale patterns on polymer substrates is described. Specifically, the patterning of arrays of nanoscale source-drain electrode pairs with continuous interconnects to the millimeter length scale is shown, as well as the fabrication of hundred-nanometer gate features hierarchically patterned over large areas. These patterned polymeric substrates can also used in conjunction with semiconductor nanowires to assemble devices such as field-effect transistors.

In nanoimprint lithography (NIL), a relief pattern is generated via compression molding of an imprintable polymer by a stamp. This pattern is transferred to the underlying substrate by anisotropic reactive ion etching (RIE), followed by material deposition and lift-off of the remaining polymer. In this example, reproducible NIL at room temperature on plastic substrates with approximately hundred nanometer resolution metal electrode structures is described. In some cases, NIL may be used to form hierarchical patterns up to the millimeter scale. This example demonstrates that imprint lithography is capable of uniformly patterning flexible, polymeric surfaces in a single ambient temperature step with nanometer scale resolution. Furthermore, the electrodes patterned by NIL may be combined with other devices. As an example, the electrodes may be combined with inorganic semiconductor nanowires to generate nanoscale transistors, which may offer the potential for single-crystal semiconductor device properties on flexible substrates.

A schematic diagram for the NIL process used in this example is shown in FIG. 2. A plastic substrate 20 coated with SiO₂ 22 and lift-off resist 24 was prepared (FIG. 2A), then imprinted using a Si/SiO₂ stamp 26 (FIG. 2B). The NIL pattern was then transferred to substrate 20 in successive RIE, metal deposition, and lift-off steps FIG. 2C. The substrate was a 100 micrometer thick poly(ethylene terephthalate) material (Mylar, CP Films) coated with approximately 100 nm thick indium tin oxide (ITO). The ITO, which facilitates electron microscopy imaging, was insulated with approximately 500 nm of SU-8 (Microchem).

The first step included the deposition of a resist for room-temperature imprinting. Lift-off resist (LOR 3A, MicroChem Corp.) was used in this example. Lift-off resist was found to function as a good material since it could be reproducibly imprinted at room temperature, removed cleanly from the inorganic stamp without anti-adhesion agents, and etched at controlled rates by RIE: In the first step, lift-off resist was deposited over a thin SiO₂ layer on the plastic substrate material: 50 nm of SiO₂ and 300 nm of LOR were deposited by electron beam evaporation and spin-coating, respectively, on the substrate. The SiO₂ layer was used in this example to improve metal adhesion and was not found to affect flexibility.

Second, the lift-off resist was imprinted at room temperature using a Si/SiO₂ stamp (400 micrometer/600 nm; Silicon Sense). 100 nm scale oxide features on the stamp were produced using standard electron beam lithography and deposition procedures. The patterns were formed using a press at 10 MPa for 10 s to 20 s, with the plastic substrate supported on a silicon wafer mounted on the base of the press. The imprinted pattern was transferred to the substrate by RIE (CF4 plasma at 100 W and 100 mTorr) followed by thermal deposition of 10 nm chromium and 50 nm gold. The polymer and metal were subsequently lifted off in Remover PG (MicroChem) at 80° C. After exposure and development, 200 nm SiO₂ was deposited onto the patterned substrate by electron beam evaporation, then the PMMA/SiO₂ was lifted off in acetone. The stamps were generally found to be reusable for at least tens to hundreds of times without significant wear or loss of resolution. Finally, the imprinted lift-off resist was etched to the SiO₂ layer using RIE, and metal electrodes were then deposited by thermal evaporation.

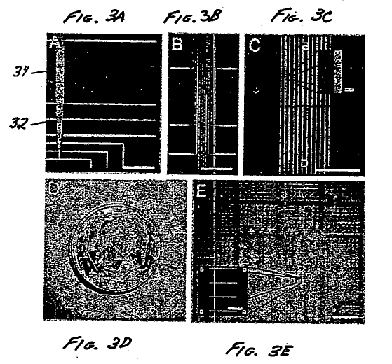

This approach was also used to reproducibly fabricate nanometer scale metal features over large areas on plastic substrates (see, e.g., FIG. 3). For instance, patterned arrays of split-electrode pairs were fabricated that can function as source-drain (SD) contacts with integrated interconnects for field-effect transistors (FETs). FIG. 3A is an optical image showing an array of SD electrodes and interconnect wires extending over several hundred micrometers. The larger scale interconnects included 1 micrometer width features. The scale bar represents 100 micrometers. FIG. 3B is an expanded view of region 32, while FIG. 3C is an SEM of an Y expanded view of region 34. The scale for bar in FIG. 3B is 25 micrometers and in FIG. 3C is 20 micrometers. It was observed that the micrometer width interconnect lines transitioned smoothly to about 200 nm width SD lines, even with right-angle turns used to route the lines from the array (FIG. 2B). It was also observed that the 200 nm width SD electrode array was substantially uniform with a 2 micrometer pitch and a 500 nm gap between each split electrode pair (see FIG. 2C). In FIG. 3C, the inset is an SEM image showing 200 nm width channel lines. The scale bar in the inset is 200 nm. This method can also be used to assemble parallel arrays of nanowire or nanotube devices on flexible or hard substrates, for example, by exploiting selective chemical modification of the SD electrode pairs and/or with electric fields.

Room-temperature NIL techniques were also used to pattern arrays of single metal lines that could be used as gate electrodes in FETs or as floating gates in nonvolatile memory applications. A low-resolution optical image of a patterned mylar substrate superimposed on a coin (FIG. 3D) highlights the transparent character of the plastic substrates used in this example. The border is outlined by a dashed line and the patterned gate array is highlighted by the central box. Additionally, this figure is an example of a pattern that is large enough to be visible to the naked eye. Higher resolution optical images of hierarchically patterned arrays of gate electrodes (FIG. 3E) further show that NIL can be used to yield about 300 nm width gate lines in highly regular 135 micrometer×105 micrometer arrays tiled over a substrate, where the arrays are on the millimeter scale. The scale bar is 100 micrometers. The inset of FIG. 3E is an SEM image of a gate array block, where corner squares are alignment marks. The scale bar is 5 micrometers in that inset. In addition, this image highlights micron-wide crosses and squares that were patterned simultaneously with the gate electrodes; these latter features can also be used to enable subsequent lithographic alignment and device fabrication.

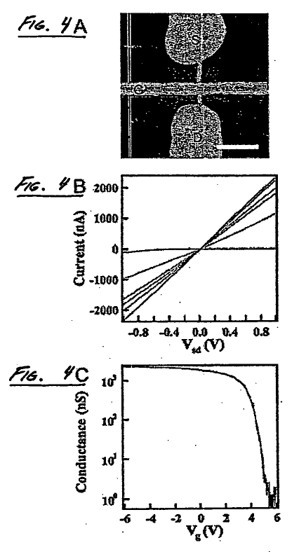

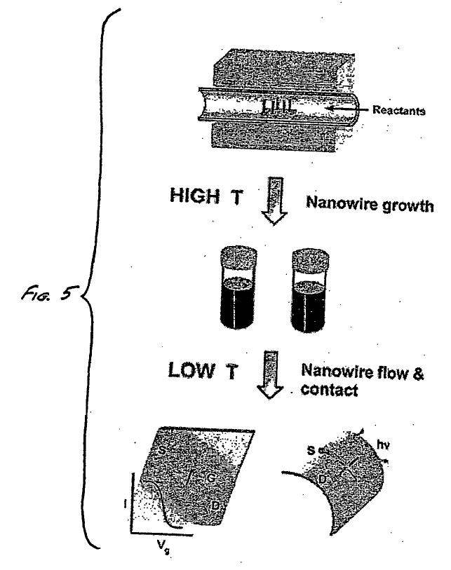

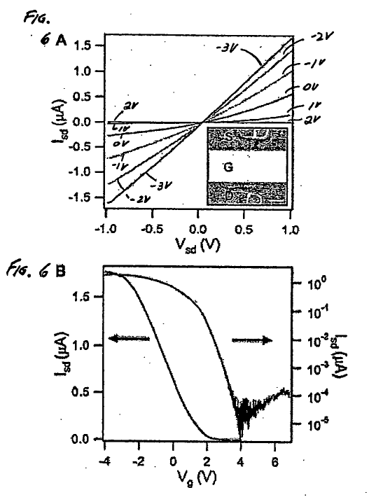

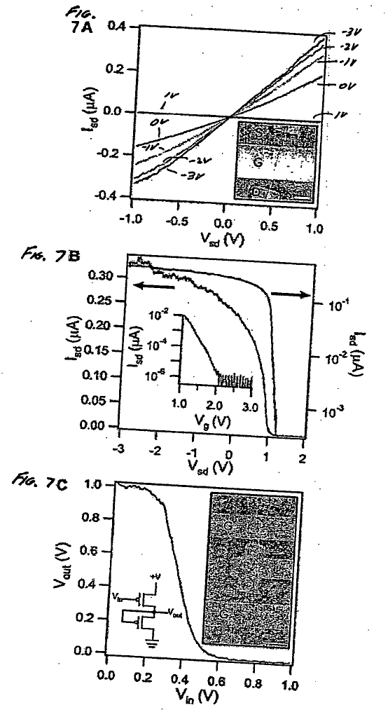

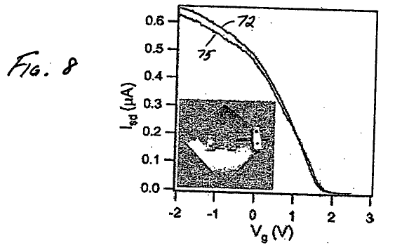

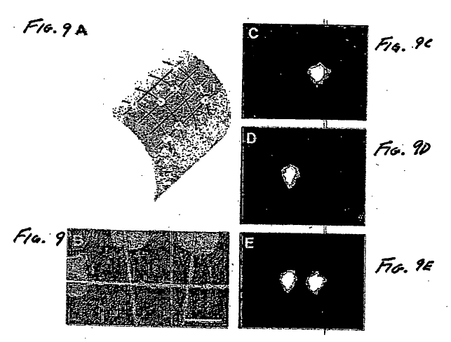

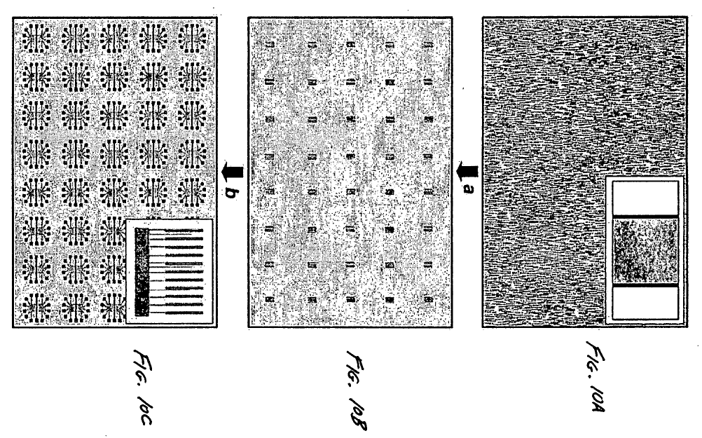

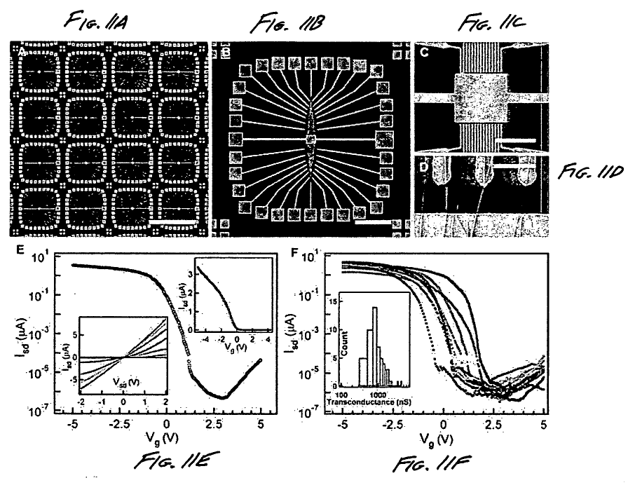

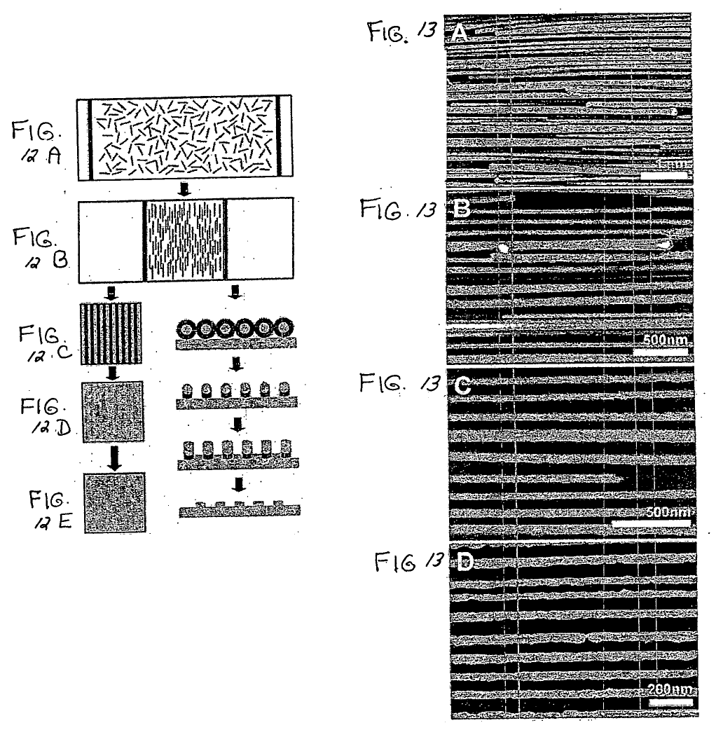

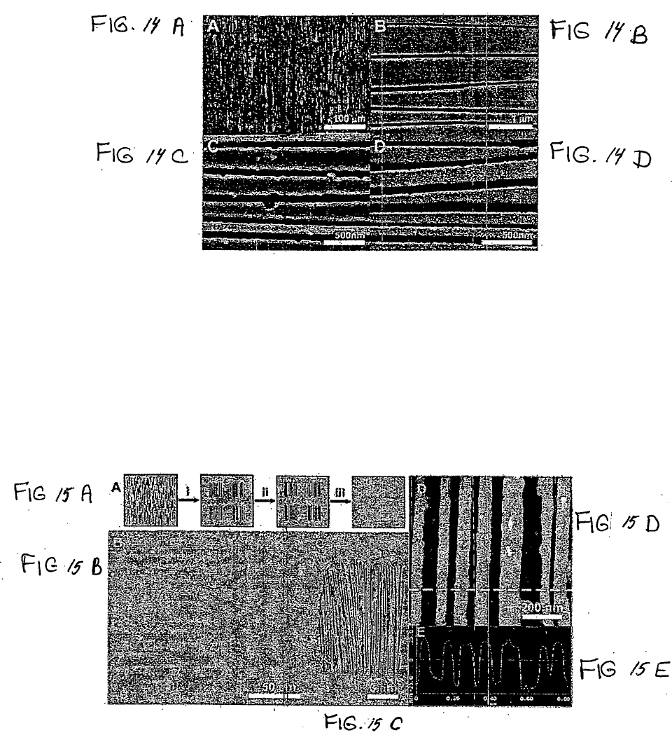

The gate electrodes of FIG. 3 were also used to create silicon nanowire (SiNW) FETs on flexible plastic substrates (FIG. 4) by combining bottom-up assembly with the top-down NIL approach. FIG. 4A is an SEM image of a 20 nm p-SiNW (vertical) crossing an imprint-patterned metal gate (G) electrode. The scale bar is 1 micron.

A solution of p-type SiNWs were flow-aligned in a direction perpendicular to the gate electrode arrays, producing a nanoscale FET at the cross point between a gate and SiNW (FIG. 4A). Ethanol solutions were used to flow-align single-crystal p-type SiNWs in a direction perpendicular to the gate features. Contacts to the SiNWs and gates were defined by electron beam lithography and subsequent electron beam deposition of 60 nm palladium and 50 nm gold. FIG. 4B shows current versus S-D voltage (I-V_{sd}) data recorded on a typical crossed-junction SiNW FET. This figure illustrates gate-dependent I-V_{sd} curves recorded on a 20 nm p-SiNW. The gate voltages (V_{g}) were −3 V, −1 V, 0 V, 1 V, 3 V, and 5 V, when read from top to bottom at positive V_{sd}. The I-V_{sd} curves, which were recorded at different gate voltages (V_{g}), were very linear, which suggested that the SD contacts were ohmic. As V_{g} increased, the slopes of the individual I-V_{sd} curves decreased, which suggested p-type FET behavior. Plots of the conductance versus V_{g} (FIG. 4C) showed that the transconductance of this device was about 750 nA V⁻¹. This value is within a factor of 2 of core/shell nanowire devices fabricated on conventional single crystal Si/SiO₂ substrates. It should be noted that this is not an optimized structure and the device performance could be improved by, for example, decreasing the dopant concentration and/or minimizing trap states in the dielectric.

Thus, this example demonstrates various NIL techniques for fabricating nanometer through millimeter-scale features on flexible plastic substrates over large areas at room temperature. The ambient temperature NIL patterning technique shown in this example may be used to produce uniform features in a parallel and repeatable manner. Further, these techniques have been combined with bottom-up assembly to fabricate SiNW FETs on flexible plastic substrates with device performances similar to nanowire FETs fabricated on conventional single-crystal substrates. The development of simple and reproducible high-resolution patterning of plastics using NIL combined with the versatile function of nanowire building blocks opens up exciting opportunities over many length scales for electronics and photonics.

### EXAMPLE 2

The merger of nanoscale building blocks with flexible and/or low cost substrates could enable the development of high-performance electronic and photonic devices with the potential to impact a broad spectrum of applications. This example demonstrates that high-quality, single-crystal nanowires can be assembled onto inexpensive glass and flexible plastic or polymer substrates to create basic transistor and light-emitting diode devices.

In this example, the high-temperature synthesis of single-crystal nanowires is separated from ambient-temperature solution-based assembly to enable the fabrication of single-crystal-like devices on virtually any substrate. To illustrate this, silicon nanowire field-effect transistors were assembled on glass and plastic substrates. These devices displayed device parameters rivaling those of single-crystal silicon and exceeding those of state-of-the-art amorphous silicon and organic transistors currently used for flexible electronics on polymeric substrates.

This example illustrates a synthetic approach that utilizes the solution-based assembly of high-performance inorganic semiconductor nanowire (NW) devices, where the functional properties are defined by nanowire building blocks used in the assembly process. This approach is illustrated in FIG. 5. The synthesis of nanowire building blocks was carried out under conditions optimized to yield high-quality single-crystal materials, where the desired electronic and/or photonic functions are defined by material composition, structure, and diameter. In this example, single-crystal p-SiNWs were grown via a gold-nanocluster-catalyzed method using 20-nm gold nanoclusters (Ted Pella) and SiH₄/B₂H₆ as the reactants. A Si/B atomic ratio of 4000:1 was used for the nanowire transistors. Such synthesis techniques include those described in, for example, Ser. No. 09/935,776, entitled “Doped Elongated Semiconductors, Growing Such Semiconductors, Devices Including Such Semiconductors, and Fabricating Such Devices,” filed Aug. 22, 2001, published as Publication No. 2002/0130311 on Sep. 19, 2002; or Ser. No. 10/196,337, entitled, “Nanoscale Wires and Related Devices,” filed Jul. 16, 2002, published as Publication No. 2003/0089899 on May 15, 2003, each incorporated herein by reference. The growth phase of the nanowires is independent of the stage in which active devices are fabricated, thus, thermal and other substrate limitations were not considered.

The devices were fabricated on alkali-free glass wafers (Plan Optik) and 100-micron-thick poly(ethylene terephthalate) (Mylar, CP Films) coated with approximately 100-nm thick indium tin oxide (ITO), which facilitates electron microscopy. The glass substrates were used without further treatment, and the plastic substrates were spin-coated with 500 nm of SU-8 (Microchem Corp.) and 50 nm of SiO₂ to isolate the conducting ITO and/or to provide a surface with good metal adhesion. Gate electrodes were defined either by photolithography or by electron beam lithography and were metallized via the thermal evaporation of Cr/Au (10 nm/40 nm). A 20-nm layer of SiO₂ was thermally deposited over the gate electrodes on the glass substrates to prevent shorting between the nanowires and gates during annealing. The electrodes were defined by electron beam lithography and were metallized with nickel (80 nm) and palladium (80 nm) for glass and plastic respectively. No annealing was carried out on plastic substrates, although the contacts on glass were annealed at 250° C. (2 min) and 360° C. (1 min).

Next, as illustrated in FIG. 5, the nanowires were isolated as stable solution suspensions useful for the deposition and patterning of devices. The use of nanowire suspensions enabled, via the sequential transfer of distinct nanowires, the introduction of very different types of functions on the same substrate. In some cases, high aspect ratio nanowires could be interconnected without the need for advanced lithography. Solution-based assembly of the nanowires on substrates then yielded devices having diverse functionalities, as further discussed below.

FIG. 6 illustrates the characterization of p-type silicon nanowire field-effect transistors (p-SiNW FETs) that were fabricated on glass substrates. To produce the device shown in the inset in FIG. 6A, gate electrodes were patterned on a glass substrate, fluid-directed assembly of the nanowires across the gate electrodes was performed, and lithography and metallization techniques were used to form source-drain contacts to the nanowires. The gate dielectric used in these experiments was either an approximately 2 nm thick shell of SiO₂ surrounding the SiNWs, or a 20-nm-thick layer of SiO₂ deposited on the gate electrodes, prior to nanowire assembly.

FIG. 6A illustrates I_{sd} vs V_{sd} curves for a 20-nm p-SiNW FET on glass. The curves correspond to V_{g}'s of −3, −2, −1, 0, 1, and 2 V, respectively. The inset is a scanning electron microscopy (SEM) image of the device. The source (S), drain (D), and gate (G) are labeled. The scale bar represents 1 micron. These curves recorded for different values of the gate voltage (V_{g}) exhibit a linear response. This linear response shows that contacts behave, at least in a practical sense, as generally ohmic, suggesting that contacts can be made on glass substrates.

FIG. 6B illustrates a graph of I_{sd} versus V_{g} (V_{sd}=1 V) for the device shown in the inset in FIG. 6A, plotted on a linear scale (left axis, left curve) and log scale (right axis, right curve). The log-scale plot consists of two curves recorded at two sensitivities and joined for clarity. This figure shows certain characteristics of these nanowires FETs. The p-SiNW devices exhibited relatively large currents of a about microampere (V_{sd}=1 V). The transconductance, dI_{sd}/dV_{g}, that is obtained from the linear portion of the data had a value of about 460 nA V⁻¹ for the device shown in the inset in FIG. 6A and yielded a hole mobility of about 365 cm² V⁻¹ s⁻¹. The hole mobility value was generally comparable to, or larger than, that previously observed in single-crystal p-type silicon. An extension of this linear region yielded a threshold voltage of 1.7 V. In addition, an examination of the full I_{sd} versus V_{g} curve showed an on/off ratio of about 10⁵ and a subthreshold slope of about 550 mV per decade change in current.

A similar approach was used to assemble p-SiNW FETs on flexible plastic substrates, prepared using similar techniques as those described for glass substrates. FIG. 7A illustrates several p-SiNW devices that were assembled on plastic. FIG. 7A illustrates I_{sd} vs V_{sd} curves for a 20-nm SiNW transistor on a Mylar substrate, for V_{g}=−3, −2, −1, 0, and 1 V, respectively. The inset is an SEM image of the nanowire device. The source (S), drain (D), and gate (G) are labeled. The scale bar represents 1 micrometer. The I_{sd} versus V_{sd} data recorded for different values of V_{g} exhibited a linear response and thus demonstrate that ohmic contacts to the SiNWs were achievable on the plastic substrates using post-nanowire synthesis processing performed entirely at room temperature. In addition, other important metrics of these nanowire transistors were comparable to those found on glass substrates.

FIG. 7B is a graph of I_{sd} vs V_{g} (V_{sd}=1 V) for the device shown in the inset of FIG. 7A, plotted on a linear scale (left axis, left curve) and log scale (right axis, right curve). From the I_{sd} versus V_{g} curves, a transconductance value of 650 nA V⁻¹ and a threshold voltage of 1 V were obtained. The corresponding mobility calculated for this device was found to be 135 cm² V⁻¹ s⁻¹. An analysis of the subthreshold region of these data further revealed an on/off ratio of about 10⁵ and a subthreshold slope of about 175 mV per decade change in current.

Thus, p-SiNW transistors assembled on plastic and glass substrates exhibited similar characteristics. The on current for the nanowire/plastic device shown in FIG. 7B was somewhat lower than that for a similar nanowire/glass structure FIG. 6b, although measurements of other nanowire/plastic transistors (data not shown) showed values (1.2 microamperes to 2.5 microamperes) that were similar to those for glass.

The assembly of high-performance SiNW devices on flexible plastic substrates can be readily extended to more complex structures. For example, a high aspect ratio p-SiNW as an inverter or logic NOT device was prepared by defining two FETs on a single nanowire. One of the transistors is used as a switch, and the other functions as a compensating resistor. FIG. 7C is a graph illustrated V_{out vs V}ᵢₙ for a nanowire inverter assembled from a p-SiNW on a plastic substrate. The left inset shows a schematic of the device, while the right inset is an SEM image of the device, in which the nanowire is oriented in the vertical direction crossing two gates (G). The scale bar represents 2 micrometers. The voltage output (Vₒᵤₜ) versus voltage input (Vᵢₙ) of this device showed that Vₒᵤₜ was high (1 V) when Vᵢₙ was low (0 V) and that the output dropped rapidly to a low value as the input was increased. This Vₒᵤₜ versus Vᵢₙ data showed that the inverter has a gain, |dVₒᵤₜ/dVᵢₙ|, of about 4. The inverter operated within a 1 V to 4 V range, and may thus be advantageous for certain low-power applications. These nanowire devices fabricated on plastic and glass could also be improved, for example, by using multi-nanowire devices to increase on currents, employing more sophisticated core/shell nanowire structures 18 designed to produce high mobilities, and/or by incorporating high-kappa gate dielectrics.

### EXAMPLE 3

This example illustrates nanowire transistor devices that were configured as low-threshold logic elements with gain; the high-performance characteristics were relatively unaffected by operation in a bent configuration or by repeated bending. In this example, a nanowire/plastic device similar to that described above with reference to the inset in FIG. 7A was used. The p-SiNWs used in this example to form p-n LEDs were core/shell structures 18 consisting of a 20-nm-diameter intrinsic silicon core and a 10-nm shell (250:1 Si/B).

The devices were fabricated on alkali-free glass wafers and 100-micron-thick poly(ethylene terephthalate) coated with approximately 100-nm-thick indium tin oxide, using techniques similar to those described in Example 2. The electrodes were defined by electron beam lithography and were metallized with Ti/Au (60/60 nm).

A comparison of I_{sd} versus V_{g} data recorded when the nanowire/plastic device was flat versus bent to a radius of curvature of 0.3 cm (FIG. 8) showed that there was only a small change in the bent state. There was a slight decrease in current for the device in the bent configuration, although this change was less than 10% for every point in the region of largest current drop, −2 V to 1 V, with an average decrease of about 5%. This change was small, given the large stresses on the chip in the bent state, thus showing the robust nature of the SiNW/plastic transistors and the potential for high-performance flexible devices. FIG. 8 shows a graph of I_{sd} vs V_{g} for a NW transistor device measured when the substrate was flat (curve 72) and bent to a radius of curvature of 0.3 cm (curve 75). The inset in FIG. 7 is a photograph of the device used for bending the flexible plastic chip and securing it during measurement. The chip is highlighted with a black dashed line.

### EXAMPLE 4

This example illustrates the assembly of gallium nitride nanowire UV-light-emitting diodes on flexible plastic substrates. The assembly of crossed-nanowire light-emitting diodes (LEDs) on plastic substrates may enable the development of flexible self-emitting displays. Such nanowires may be robust, inorganic materials, different nanowires may have a wide range of spectrally pure output colors, and nanowire transistor devices and LED devices may be integrated together, potentially without the need for polycrystalline silicon. In this example, crossed-nanowire UV LEDs were assembled from n-type GaN nanowires and p-type SiNWs onto plastic substrates using sequential orthogonal fluid-directed assembly.

Single-crystal GaN nanowires were prepared by nickel-metal-catalyzed chemical vapor deposition. Stable solutions of nanowires were prepared by sonication of the growth substrate in ethanol for 5 s to 10 s. FIG. 9A is a schematic of a flexible self-emitting display consisting of a crossed-nanowire LED array on a flexible plastic substrate. FIG. 9B is an SEM image of two p-SiNWs (vertical) crossing an n-type GaN NW to form two LEDs on the plastic substrate. The scale bar represents 1 micron. When either one or both of the p-n diodes of a representative 1×2 n-GaN/p-Si crossed nanowire device (FIG. 9B) were forward-biased, localized and addressable emission was observed from the junctions (FIGS. 9C-9E). FIGS. 9C-9E are electroluminescence (EL) images of localized emission from forward-biased Si—GaN junctions. The junctions can be driven individually (FIGS. 9C-9D) or simultaneously (FIG. 9E). Thus, these nanowire UV LEDs were found to also be able to maintain their emissive properties upon repeated cycles of bending/unbending of the plastic substrate, thus demonstrating the potential for the fabrication of high-performance optoelectronic systems on flexible plastics.

### EXAMPLE 5

This example illustrates a large-scale integrated array of semiconductor nanoscale wire devices, according to an embodiment of the invention. Large-scale assembly and integration of nanoscale wires and nanotubes into functional devices could be critical to the development of electronic and photonic nanotechnologies. This example illustrates a strategy that enables parallel and scalable interconnection of nanoscale wire devices over large areas. In this example, hierarchically organized arrays of silicon nanoscale wires were connected to microscale metal electrodes in high yield using photolithography, without the need for registering individual nanoscale wire-metal contacts. The thousands of silicon nanoscale wire field-effect transistors in large-scale arrays fabricated via this approach exhibited high-performance device characteristics and good reproducibility. The general applicability of this approach to other nanoscale wire building blocks could enable a broad range of integrated applications to be assembled from these nanomaterials.

In this example, the approach for large-scale fabrication of integrated nanoscale wire devices (FIG. 10) involved the following three steps. First, uniaxially compressed nanoscale wire-surfactant monolayers in a Langmuir-Blodgett trough were transferred en masse to a planar substrate to yield parallel nanoscale wires covering areas of up to tens of square centimeters (FIG. 10A). Second, the uniform layer of nanoscale wires were patterned using photolithography to yield discrete size nanoscale wire arrays on the substrate surface (FIG. 10B). These steps allow the average nanoscale wire spacing, array dimensions and array repeat period to be independently varied. Third, electrode patterns for interconnecting the nanoscale wires in the arrays are defined in a second photolithography step, in which alignment is made only relative to the larger repeating array structures (FIG. 10C).

Silicon nanoscale wires were grown using 20 nm gold nanoclusters (Ted Pella, Redding, Calif.) in a nanocluster-catalyzed chemical vapor deposition process, where silane was used as the silicon reactant and diborane as a p-type dopant; nanoscale wires were prepared with Si:B gas ratios of 4000:1 and 8000:1. The nanoscale wires were aligned and then transferred to degenerately doped (resistivity<0.005 Ohm cm) silicon (100) substrates coated with 60 nm thick sputtered ZrO₂ (Silicon Valley Microelectronics, San Jose, Calif.). Aligned nanoscale wire layers were patterned by photolithography, and the nanoscale wires outside the patterned areas were removed by sonication in deionized water.

To fabricate the electrode arrays, the patterned nanoscale wire arrays were coated with photoresist (Shipley S1805), baked at 110° C. for 4 min, and the exposed for about 0.7 s following mask alignment. The substrates were developed in the metal-ion-free MF319 (Shipley) for 1 min, rinsed in deionized water for 2 min, cleaned with an O₂ plasma (25 W for 60 s at 0.5 Torr O₂), and then etched in buffered HF (pH=5, 40% total fluoride concentration) for 8 s. Metal electrodes of Ni (70 nm) were deposited by thermal evaporation, followed by lift-off (Shipley 1165) of resist and unwanted materials. These chips were rinsed with acetone and isopropanol, and then annealed at 350-390° C. for 1 min in H₂/He carrier gas using a rapid thermal annealer (Jipelec JetFirst, Montpellier Cedex, France). Electrical transport measurements were made at room temperature with a high-precision semiconductor analyzer (Agilent 4156C, Agilent Technologies, Palo Alto, Calif.) and a probe station (Desert Cryogenics, Tucson, Ariz.).

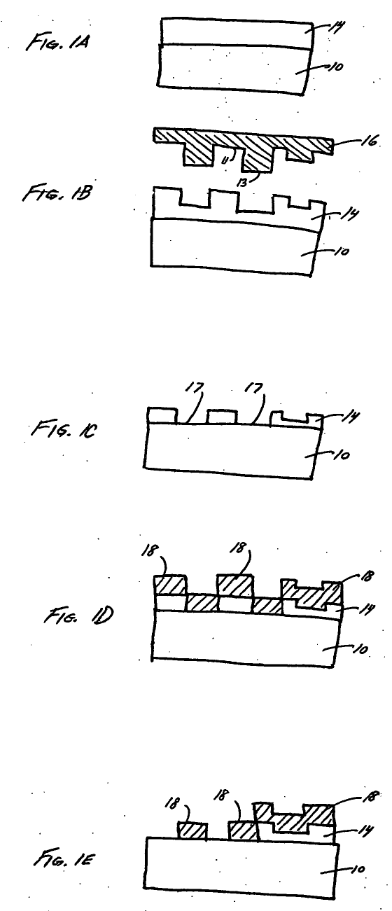

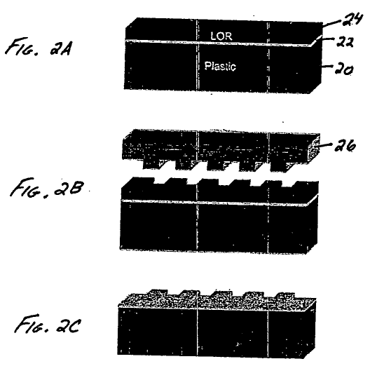

In FIG. 10A, a substantially uniform parallel layer of aligned nanoscale wires on a substrate surface is shown. The nanoscale wires were uniaxially-aligned at the air-water interface on a Langmuir-Blodgett trough (inset) with a controlled average spacing. The uniform nanoscale wire layer was hierarchically patterned into parallel nanoscale wires arrays by photolithography, where the nanoscale wires were removed from regions outside of a predefined pattern (FIG. 10B). Large-scale device arrays were then fabricated by defining complementary electrode arrays using photolithography. (FIG. 1 ° C., inset). This inset shows that the array includes a high fraction of the interconnected nanoscale wires without requiring registration of individual electrodes.

In FIG. 10C, the interconnects between the nanoscale wires and the electrodes were made without registering the electrode pattern to the individual nanoscale wires. The nanoscale wires in the arrays exhibited well-defined overall alignment and average spacing, although there were small fluctuations in the alignment direction and spacing. One-to-one registration of each nanoscale wire with each electrode was not achieved however. Specifically, statistics dictate that a high fraction of electrodes will be bridged by a single nanoscale wire when the average nanoscale wire spacing is set slightly larger than the electrode width (FIG. 10C, inset). Variations in the alignment also do not affect the ability to make two contacts to a given nanoscale wire when nanoscale wires within a given array share a common electrode and independent electrical contacts are only made for the second contact. Therefore, at the expense of a priori knowledge of which specific nanoscale wires will be contacted, a single electrode pattern can be repeated over a large area to interconnect any nanoscale wire array with minimal attention to alignment. It should also be understood that the same concept can be applied for interconnecting regular arrays of crossed nanoscale wires, because contacts are only required to single ends of the orthogonal sets of nanoscale wires to address elements in the crossed array.

### EXAMPLE 6

In this example, large arrays of single p-type silicon nanoscale wire FETs were prepared, using techniques similar to those described with respect to Example 5. Characterization of the resulting nanoscale wire device arrays by optical and electron microscopy illustrated a hierarchy of structures, as shown in FIG. 11. In FIG. 11A, the device included sub-arrays with a 1 mm array pitch repeated over a 1 cm² substrate, which highlights the large scale over which device arrays were produced by this patterning technique. FIG. 11A is an optical micrograph of integrated metal electrode arrays deposited on top of patterned parallel nanoscale wire arrays. The scale bar represents 1 mm. FIG. 11B is an optical micrograph of one repeat unit from FIG. 11A, showing a single sub-array unit with features from 70 micrometers (contact pad size) to 1 micrometer (smallest electrode). The scale bar represents 200 micrometers. FIG. 11C shows central electrode arrays on a 3 micrometer electrode pitch. FIG. 11C is a field emission scanning electron microscope (SEM) image of the central active region of a repeat unit. The individual nanoscale wires, not easily visible in the image, are connected between the center common electrode and independent finger electrodes. The scale bar represents 40 micrometers. In FIG. 11D, individual 20 nm diameter nanoscale wires connected between the finger electrodes and the common electrode are shown. This figure is an SEM image of three nanoscale wire devices connected between the common and finger electrodes. The scale bar indicates 3 micrometers. This figure also illustrates that single nanoscale wires can fall between two metal electrodes as expected statistically, although the overall nanoscale wire alignment prevents such defective devices from adversely affecting properly interconnected nanoscale wires. Notably, approximately 80% of the 3000 possible electrode connections available on a single substrate chip were bridged by nanoscale wires when the spacing of the aligned nanoscale wires was closely matched to the electrode width (about 1 micrometer in this example).

The device characteristics of p-type silicon NW FETs fabricated in this parallel manner were assessed by electrical transport measurements made on a random sampling of the thousands of NW devices. FIG. 11E is a plot of I_{sd} vs. V_{g} for a typical device in the array showing an on/off ratio of 7×10⁶. The source-drain voltage was 1 V. The upper inset of FIG. 11E shows a linear scale I_{sd} vs. V_{g} plot and the lower inset shows a family of I_{sd} vs. source-drain voltage (V_{sd}) plots at different gate voltages for the same device. The various curves correspond to V_{g} of −5, −4, −3, −2, −1, 0 and 3 V, respectively. FIG. 11F is a plot of I_{sd} vs. V_{g} at a V_{sd} of 1 V for a sampling of devices from the large arrays. The inset of FIG. 11F is a histogram of the 13 transconductance values observed for a sampling of devices in the large-scale array. The nanoscale wires used in these devices were grown with a Si:B ratio of 4000:1

Representative source-drain current (I_{sd}) versus source drain voltage (V_{sd}) curves (lower inset, FIG. 11E) are linear for small V_{sd} and show saturation at negative voltages as expected for p-type FETs. A logarithmic plot (FIG. 11E) of I_{sd} versus gate voltage (V_{g}) demonstrated an on/off current ratio of greater than 7×10⁶ and a subthreshold slope of about 160 mV/decade. The increase in I_{sd} for V_{g}>2.5 V is believed to be due to gate leakage. A linear plot of I_{sd} versus V_{g} (upper inset, FIG. 2E) yielded a peak transconductance, dI_{sd}/dV_{g}, of about 1250 nA/V. Moreover, studies of a large number of devices show that these results are reproducible (data not shown). I_{sd} versus V_{g} plots for 9 devices (FIG. 11F) all exhibited on/off current ratios greater than 106 and substhreshold slopes below 250 mV/decade, where the highest on/off ratio was 10⁷ and the lowest substhreshold slope was 140 mV/decade. A histogram of the observed peak transconductance values for these and many other devices (inset, FIG. 11F) showed a most probable value close to 1000 nA/V and a maximum value of 4300 nA/V corresponding to a calculated hole mobility of 307 cm²V s. These device characteristics were comparable to or exceed the best values reported previously for silicon NW FETs fabricated individually by electron-beam lithography, and moreover, were greater than those of amorphous silicon thin-film transistors (TFTs), similar or better than p-type polysilicon silicon TFTs, and even crystalline silicon devices.

### EXAMPLE 7

This example illustrates a general and scalable method for patterning nanometer scale lines hierarchically over large areas using nanowires as masks for etching and deposition. Core-shell nanowires with controlled diameter and shell dimensions were aligned with nanometer to micrometer scale pitches using a Langmuir-Blodgett approach and then transferred en masse to planar substrates. Transferred nanowires were used as deposition masks to define metal lines with pitches from the nanometer to micrometer scale over centimeter square areas. Hierarchical parallel nanowire arrays were also prepared and used as masks to define nanometer pitch lines in 10×10 micron arrays repeated with a 25 micrometer array pitch over centimeter square areas. This nanolithography method represents a highly scalable and flexible pathway for defining nanometer scale lines on multiple length scales and thus has substantial potential for enabling the fabrication of integrated nanosystems.

The general approach used in this example is illustrated schematically in FIG. 12. Surfactant-stabilized nanowires were uniaxially compressed on a Langmuir-Blodgett (LB) trough to produce aligned nanowires with a pitch (the center-to-center nanowire-nanowire separation) controlled by the compression process (FIG. 12A). The aligned nanowires were then horizontally transferred en masse onto hydrophobic substrates to form uniformly ordered parallel arrays (FIG. 12B). Because compression of nanowires below a pitch of about 100 nm-200 nm leads to increasing aggregation due to strong inter-nanowire attractive forces, core-shell nanowires were used in which the core diameter and shell thickness were independently varied to enable control of pitch at the nanometer scale. Following transfer, selective anisotropic etching was used to remove the oxide shell of coreshell nanowires and, if desired, transfer the line-pattern to the underlying substrate surfaces (FIG. 12C). In addition, other materials, such as metals, were deposited in some cases using the aligned nanowires as shadow masks to create arrays of nanoscale wires (FIG. 12D). Finally, the nanowire masks were removed by isotropic wet etching and sonication to expose the etched or deposited parallel line features (FIG. 12E).

FIG. 12A shows alignment of nanowires on the water surface of a Langmuir-Blodgett trough. FIG. 12B shows transfer of the substantially aligned nanowires onto a substrate. The top view of FIG. 12B (left) illustrates nanowires compressed to finite pitch. The cross-sectional view (right) shows the case of nanowires compressed to close-packed where the nanowires have a core-shell structure. FIG. 12C shows selective anisotropic etching of the oxide shell of core-shell nanowires. FIG. 12D shows deposition of metal or other materials. FIG. 12E shows removal of the nanowire mask to yield parallel lines over the entire substrate surface.

This approach was demonstrated with the fabrication of high density parallel metal lines. The nanowires used in these studies were core-shell Si—SiO₂ nanowires prepared with nearly monodisperse diameters and aspect ratios of at least 500-1000:1 using nanocluster catalyzed chemical vapor deposition. Stable nanowire suspensions in isooctane-2-propanol mixed solvents were spread on the surface of the aqueous phase in a LB trough, uniaxially compressed to close-packed structures, and then transferred to silicon substrates. Field-emission scanning electron microscopy (SEM) images showed that the transferred nanowires exhibit good alignment over many micrometers and were in a close-packed configuration (FIGS. 13A-13B). The average nanowire pitch, about 90 nm, was consistent with the overall diameter of the core-shell nanowire (50 nm Si core and 20 nm thick SiO₂ shell) used in these experiments. FIGS. 13A-13B showed close-packed parallel Si—SiO₂ core-shell nanowires on the silicon substrate surface.

Reactive ion etching (RIE) with CHF₃ was used to remove the SiO₂ on the sides and tops of the core-shell nanowires. SEM images demonstrated that RIE produced an increase in the average spacing between nanowires to about 40 nm, although the nanowire pitch remained unchanged (FIG. 13C). These results were consistent with selective and anisotropic etching of the SiO₂ shell. FIG. 13C shows parallel nanowires after selective, anisotropic etching of the SiO₂ shell by RIE.

Last, chromium metal was deposited by thermal evaporation, and the nanowire shadow masks were removed by sequential 40% NH₄F aqueous solution etching followed by sonication in deionized water. The SEM image of the resulting sample shows well-defined parallel metal lines with an average pitch, 90 nm, and line width, 40 nm, consistent with the overall process (FIG. 13D). In FIG. 13D, 15 nm thick Cr metal lines following removal of the nanowire mask were observed.

These results demonstrate several important characteristics of this nanowire-based lithography approach. First, the line width and pitch were well-controlled via the synthesis of core/shell nanowires prior to assembly and subsequent processing steps. This offered the potential for rapidly and independently changing the line width and pitch on the nanometer scale. Second, the feature sizes defined by this method were comparable to state-of-art extreme UV lithography and approach the limit of electron-beam lithography and very recent transfer lithography studies. Third, this approach allowed the assembly of nanowires in one step over areas of 20 cm², which exceeded most other unconventional lithography methods, and, moreover, could extend the coverage to much larger areas using modified LB instrumentation.

### EXAMPLE 8

In this example, much larger width and pitch lines were fabricated. Specifically, the pitch of aligned nanowires was readily controlled from the micrometer to submicrometer scale during uniaxial compression in the LB trough, and then the nanowires were transferred en masse to substrates as shown in FIG. 14A. Nanowires transferred at larger separations were used directly as masks for the fabrication of metal lines without the RIE etching step described in Example 7. Specifically, chromium metal was deposited by thermal evaporation onto substrates with transferred parallel nanowire masks having average pitches of 0.6 micrometers, 0.3 micrometers, and 0.2 micrometers, and then the nanowires were removed by sequential 40% NH₄F aqueous etching and sonication in deionized water. SEM images of the resulting structures showed well-defined metal lines with average pitches of about 0.6 micrometers, 0.3 micrometers, and 0.2 micrometers (FIGS. 14B, 14C, and 14D, respectively). The spacing between metal lines (i.e., the dark lines in the images) was determined largely by the diameter of the nanowire used as masks, while the much larger pitch was set by nanowire-nanowire separation during the LB compression. The ability to control independently the separation and width of the metal lines during the assembly process contrasts previous examples from nanosphere lithography, where only close-packed monolayers of polymer spheres have been used for patterning.

FIG. 14A is a large-area SEM image of nanowires aligned and transferred by the LB method. The nanowire pitch was about 0.8 micrometers. FIGS. 14B, 14C, and 14D are SEM images of Cr-metal stripes with pitches of about 0.6 micrometers, 0.3 micrometers, and 0.2 micrometers, respectively. Brighter areas in these images corresponded to the metal, while the darker lines are SiO₂ substrate surface remaining after removal of the nanowire masks.

### EXAMPLE 9

In this example, a nanowire lithography approach was used to prepare discrete line arrays that are tiled in a regular and definable pattern over large substrate areas. FIG. 15A is a schematic illustration of the approach for hierarchical patterning of nanowire lithographically defined structures.

Aligned, controlled-pitch nanowires were transferred uniformly to a substrate, a pattern was defined using photolithography, and then nanowires outside the pattern were removed by sonication. The tiled nanowire arrays were then used as etch or deposition masks to fabricate line structures on the substrate as described above. To demonstrate this approach for hierarchical patterning of parallel lines, line patterns defined by 10 micrometer×10 micrometer square nanowire arrays tiled with a 25 micrometer pitch were transferred into a SiO₂ substrate surface by RIE. Large area SEM images showed clearly that the tiled square pattern was transferred to the substrate surface (FIG. 15B), and higher resolution images further demonstrated that each square included a parallel array of SiO₂ lines with widths smaller than 100 nm (FIG. 15C). The shapes of the lines were further characterized by atomic force microscopy (AFM). These measurements showed that the etched lines have a very regular height, about 50 nm, which is consistent with RIE etch time and rate (FIGS. 15D, 15E). FIG. 15D is an AFM image of seven line features recorded from one array. The z-range of the image was 80 nm. FIG. 15E is a plot of the height variation recorded along the cross section indicated by the dashed line in FIG. 15D.

This method is applicable for transferring line patterns to other substrates, for example, substrates with electronically and/or optically active surface layers, as long as selective etching conditions for the substrate versus nanowire mask can be established. This approach can also be used for hierarchical patterning of metal lines using the procedures describe above. Overall, this work demonstrates that the combination of conventional photolithography and this new nanowire lithography provides rapid and scalable access to arrays of parallel lines with well-defined order on length scales from sub-100 nm, which is defined by nanowire diameter and LB compression, to micrometer scale of square arrays, which is set by the photolithography pattern, to centimeter and much larger areas defined by the LB transfer method. Significantly, the order and length scales can be varied at each level in a facile and independent manner.

In summary, a general and scalable method has been developed for patterning nanometer scale lines hierarchically over large areas using nanowires as masks for etching and deposition. Core-shell nanowires with controlled diameter and shell dimensions were aligned with nanometer to micrometer scale pitches using the LB technique and then transferred en masse to planar substrates over areas up to 20 cm². Transferred nanowires were used as deposition masks to define metal lines with pitches from the nanometer to micrometer scale over centimeter square areas. Hierarchical parallel nanowire arrays were also prepared and used as masks to define nanometer pitch lines in 10×10 micron² arrays repeated with a 25 micrometer pitch over centimeter square areas. This nanolithography method represents a highly scalable and flexible approach for defining nanometer scale lines on multiple length scales and thus has substantial potential for enabling the fabrication of many types of periodic nanostructures and integrated nanosystems.

### EXAMPLE 10

In this example, the assembly of nanowires and nanotubes into arrays patterned on multiple length scales, useful for the realization of integrated electronic and photonic nanotechnologies, was demonstrated. A general and efficient solution-based method for controlling organization and hierarchy of nanowire structures over large areas has been developed. Nanowires were aligned with controlled nanometer to micrometer scale pitch using the Langmuir-Blodgett technique and transferred to planar substrates in a layer-by-layer process to form parallel and crossed nanowire structures. The parallel and crossed nanowire structures were patterned into repeating arrays of controlled dimensions and pitch using photolithography to yield hierarchical structures with order defined from the nanometer through centimeter length scales. In addition, electrical transport studies show that reliable electrical contacts can be made to the hierarchical nanowire arrays prepared by this method. This solution-based process offers a flexible pathway for bottom-up assembly of virtually any nanowire material into highly integrated and hierarchically organized nanodevices needed for a broad range of functional nanosystems.

In this example, a solution-based approach for hierarchically organizing nanowire building blocks en masse into integrated arrays tiled over large areas was demonstrated. nanowires were aligned with controlled nanometer to micrometer scale pitch using the Langmuir-Blodgett technique, transferred to planar substrates in a layer-by-layer process to form parallel and crossed nanowire structures over centimeter length scales, and then efficiently patterned into repeating arrays of controlled dimensions and pitch using photolithography. This solution-based method enabled the specific nanowire building block, nanowire pitch, nanowire orientation, array size, array orientation, and array pitch to be controlled independently for sequential depositions, and thus offered a flexible pathway for bottom-up assembly of nanowire and nanotube materials into integrated and hierarchically organized structures.

This approach for controlled assembly of nanowires (FIG. 16) exploits the Langmuir-Blodgett (LB) technique to uniaxially compress a nanowire-surfactant monolayer on an aqueous subphase, thereby producing aligned nanowires with controlled spacing. The compressed layer was then transferred in a single step to a planar substrate to yield parallel nanowires covering the entire substrate surface. In addition, this sequence of steps could be repeated one or more times with controlled orientation to produce crossed and more complex nanowire structures, where the nanowires can be the same or different in sequential layers. The ability to assemble a wide range of different nanowire building blocks in a flexible manner is an attribute of this bottom-up approach and distinct from other top-down fabrication methods. The Langmuir-Blodgett technique was also used to organize single layers of low aspect ratio nanorods into close-packed structures suggestive of liquid crystalline phases (see previous examples). In addition, this method was used to prepare large area nanowire masks for deposition and etching.

FIG. 16 schematically shows that nanowires in a monolayer of surfactant at the air-water interface are compressed on a Langmuir-Blodgett trough to a specified pitch (FIG. 16). In FIG. 16B, the aligned nanowires are transferred to the surface of a substrate to make a uniform parallel array. In FIG. 16C, crossed nanowire structures are formed by uniform transfer of a second layer of aligned parallel nanowires perpendicular to the first layer.

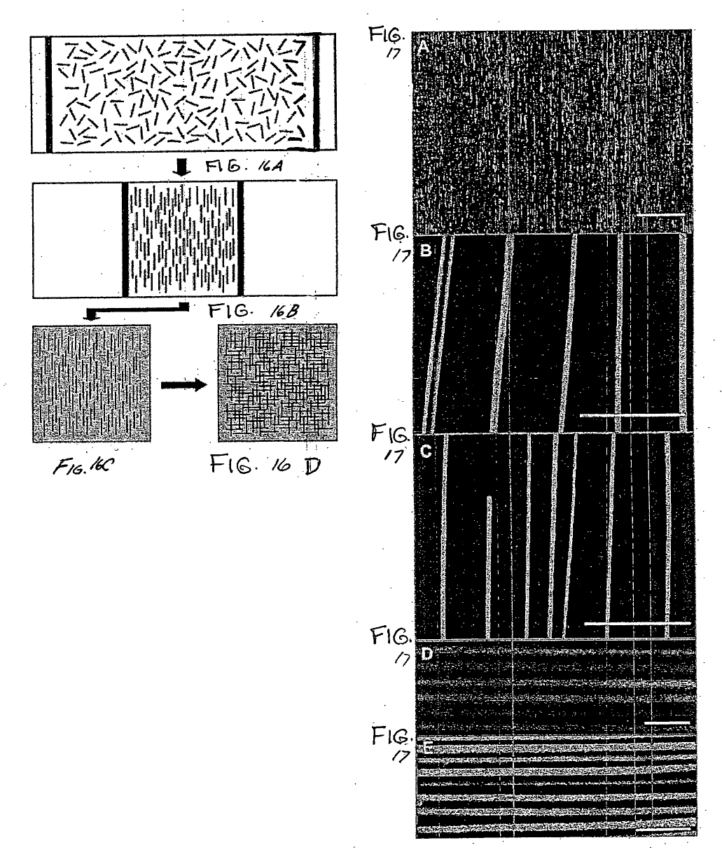

In this example, silicon nanowires that were prepared with nearly monodisperse diameters by nanocluster catalyzed chemical vapor deposition. Stable nanowire suspensions in nonpolar solvents made using the surfactant 1-octadecylamine, which coordinates reversibly to nanowire surfaces, were spread on the surface of the aqueous phase in a Langmuir-Blodgett trough and compressed. During compression, nanowires become aligned along their long axes with the average spacing (center-to-center distance) controlled by the compression process. Large area field emission scanning electron microscopy images (FIG. 17A) show that parallel nanowires were transferred with good uniformity and alignment onto substrates with areas up to 20 cm² in our experiments, although this approach can be applied to much larger area substrates. FIG. 17A shows a large area image of parallel nanowires deposited uniformly on a 1 cm×3 cm substrate. The scale bar represents 100 micrometers.

Control of the spacing of the transferred nanowires from the micrometer scale to well-ordered and close-packed structures by the compression process is also demonstrated in this example. Representative images of transferred nanowires with spacings of about 0.8 micrometers and 0.4 micrometers (FIGS. 17B and 17C) showed that the nanowires were isolated and had substantial uniaxial alignment. In general, the transferred nanowire arrays had similar qualities for spacings from about 2 micrometers (the largest studied in this example) to 200 mm. Compression to spacings below about 200 nm led to increasing aggregation due to strong inter-nanowire attractive forces, although aligned close-packed monolayer structures were still transferable. This capability was used to make ultrahigh-density arrays with the nanowire spacing controlled on the nanometer scale, by compressing nanowires coated with controlled thickness sacrificial layers, and then removing this layer once transferred. FIGS. 17B and 17C are images of aligned parallel nanowires transferred to substrates at different stages of LB compression. The scale bars in each of the figures correspond to 1 micron.

For example, core/shell Si/SiO₂ nanowires, in which the oxide shell thickness was precisely controlled during nanowire growth, were compressed to close-packed structures and transferred to substrates. Images recorded following HF etching of the oxide shells show well aligned parallel nanowires with center-to-center separations of 90 nm (FIG. 17D) and about 45 nm (FIG. 17E) that are in agreement with the values predicted based on the dimensions of the core/shell nanowires; that is, the center-to-center separation is equal to 2× (nanowire radius+shell thickness). Additionally, it was demonstrated that selective dry (i.e., reactive ion) etching could be used to remove oxide from core/shell Si/SiO₂ nanowires to produce similar structures. In addition, this approach is extendable to even finer spacings that would be difficult to achieve by top-down lithography. FIGS. 17D and 17E are images of high-density parallel nanowire arrays with average pitches of about 90 nm (FIG. 17D) and about 45 nm (FIG. 17E). Nanowires with core diameters of 70 nm and 25 nm, respectively, and 10 nm silicon oxide shell thicknesses were used for assembly. The scale bars in these figures correspond to 200 nm. These images were recorded with a field-emission scanning electron microscope.

The aligned, controlled spacing nanowire structures exhibited features similar to a nematic liquid crystal phase, including fluctuations in the average alignment direction and poor end-to-end registry (FIG. 17C). These nonuniform features were distinct from the precise structures familiar to conventional top down fabrication; however, these features do not represent serious impediments to making integrated and interconnected devices, as previously described. Specifically, interconnected finite-size arrays of nanoscale devices may be more desirable than monolithic structures for integrated nanosystems in some cases, because hierarchical organization reduces the probability that small numbers of defects will cause catastrophic failure in the whole system. Hence, by adjusting this array size to be less than the average nanowire length, the number of nanowires that fail to span the width of an array due to poor end-to-end registry could be minimized.

### EXAMPLE 11

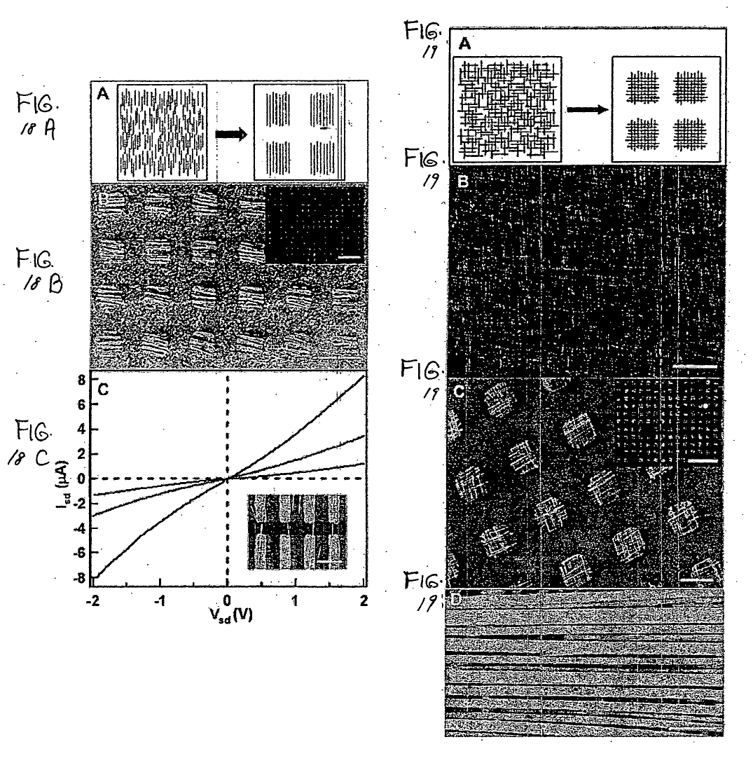

In this example, a desired hierarchical patterning of the transferred nanowire structures in a flexible and scalable manner using photolithography was demonstrated (FIG. 18). Following uniform transfer of nanowires of a specified spacing onto a substrate, photolithography was used to define a pattern over the entire substrate surface, which sets the array dimensions and array pitch, and then the nanowires outside the patterned array was removed by gentle sonication. FIG. 18A shows hierarchical patterning of parallel NW arrays by lithography, where NWs are removed from regions outside of the defined array pattern. An image of a 10 micrometer×10 micrometer square array with a 25 micrometer array pitch (FIG. 18B) showed that this method provided ready and scalable access to ordered arrays over large areas. The scale bar represents 25 micrometers. This array exhibited order on multiple length scales (40 nm diameter nanowires, 0.5 micrometer nanowire spacing, 10 micrometer array size, 25 micrometer array pitch repeated over centimeters) that are representative of the substantial control enabled by this approach. In addition, this approach can be used to define array geometries and tiling patterns more complex than square structures, as previously described.

It was also investigated whether this approach for assembling and patterning hierarchical nanowire arrays is compatible with the fabrication of nanoelectronic devices. To test this important point, electron beam lithography was used to define a series of parallel finger electrodes contacting nanowires in hierarchically patterned parallel arrays (FIG. 18C). Electrical transport measurements carried out on three of the silicon nanowire devices exhibit linear current versus voltage behavior. This linear response and the typical two-terminal resistance values, 260 kOhm-1780 kOhm, are indicative of good electrical contacts. These results demonstrate that the solution-based hierarchical assembly methodology produced electrically active nanowires, and therefore should be compatible with the goal of creating large-scale integrated, functional nanosystems. In FIG. 18C, typical linear current vs. voltage curves recorded from three nanowire devices are shown. The inset shows representative scanning electron microscopy image of four aligned NW devices defined by electron beam lithography. The scale bar represents 3 micrometers.

### EXAMPLE 12

In this example, a method of the invention was used to make crossed nanowire arrays by transferring sequential layers of aligned nanowires in an orthogonal orientation and then patterning the layers as described above (FIG. 19).

FIG. 19A illustrates hierarchical patterning of crossed nanowire arrays by lithography, where nanowires are removed from regions outside of the defined array pattern. Crossed nanowire arrays are particularly attractive targets because previous small scale studies of crossed nanowire junctions have demonstrated interesting electronic and photonic function. Large area images of two silicon nanowire layers transferred sequentially with orthogonal alignment (FIG. 19B) showed that this approach yielded relatively uniform coverage over centimeter length scales. FIG. 19B is a dark-field optical micrograph of crossed nanowires deposited uniformly on a 1 cm×1 cm substrate. The scale bar represents 50 micrometers. Images of crossed nanowire arrays (FIG. 19C), which were made by defining an array pattern with photolithography and then removing nanowires outside of the patterned areas, show that regular 10 micrometer×10 micrometer square arrays with a 25 micrometer array pitch can be achieved over large areas and that each of the square arrays consists of a large number of crossed nanowire junctions. FIG. 19C is a scanning electron microscopy image of patterned crossed nanowire arrays. The scale bar represents 10 micrometers. The inset is a large area dark-field optical micrograph of the patterned crossed nanowire arrays. The scale bar represents 100 micrometers.

In addition, ultrahigh-density crossed nanowire arrays using this method. Close-packed Si/SiO₂ core/shell nanowires were transferred in two orthogonal layers and then etched with HF to yield crossed nanowire arrays with pitches of less than 50 nm (FIG. 19D). FIG. 19D is a scanning electron microscopy image of an ultrahigh density crossed nanowire array. The scale bar represents 200 nm.

In summary, this example outlines a general and rational strategy for hierarchical organization of nanowires and represent substantial progress toward the bottom-up assembly of integrated architectures over large areas in a highly parallel and scalable manner. The facile substitution of different nanowires and changes in structural hierarchy enabled by this approach is attractive for creating integrated, functional nanosystems. For example, crossed nanowire arrays can be used as addressable nanoscale light-emitting diode sources. More generally, efforts focused on increasing the structural complexity, for example by tiling functionally distinct arrays using additional transfer steps, enables combinations of logic and memory arrays that are needed for nanocomputing or even integrated sensing and processing function.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of”, when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An article, comprising:
a substrate comprising a polymer; and
an electrically semiconductive or conductive nanoscale wire proximate the substrate, the nanoscale wire comprising at least one portion having a smallest width of less than about 100 nm.

2-71. (canceled)
